(19) United States
(12) Patent Application Publication
(10) Pub. No.: US 2025/0380499 A1
(43) Pub. Date: Dec. 11, 2025

(54) SEMICONDUCTOR DEVICE

(71) Applicant: Samsung Electronics Co., Ltd., Suwon-si (KR)

(72) Inventors: Hong Sik SHIN, Suwon-si (KR); Keun Hee BAI, Suwon-si (KR); Kwang-Yong YANG, Suwon-si (KR); Sang Eun YUN, Suwon-si (KR); Won Hyuk LEE, Suwon-si (KR); Ji-Eun HAN, Suwon-si (KR)

(73) Assignee: Samsung Electronics Co., Ltd., Suwon-si (KR)

(21) Appl. No.: 19/035,244

(22) Filed: Jan. 23, 2025

(30) Foreign Application Priority Data
Jun. 10, 2024 (KR) 10-2024-0074791

(51) Int. Cl. H10D 84/83; H10D 30/00; H10D 30/01; H10D 30/43; H10D 62/10; H10D 62/13; H10D 64/23; H10D 84/01

(52) U.S. Cl. CPC H10D 84/832; H10D 30/43; H10D 30/502; H10D 62/121; H10D 62/151; H10D 64/258; H10D 84/83138; H10D 30/014; H10D 30/0191; H10D 84/0147; H10D 84/0149

(57) ABSTRACT

A semiconductor device may include an active pattern on a substrate, first to third gate electrodes on the active pattern, a first source/drain region and a first source/drain contact between the first and second gate electrodes, a second source/drain region and a second source/drain contact between the second and third gate electrodes, a gate spacer on both sidewalls of the second gate electrode, a first interlayer insulating layer covering the first and second source/drain regions, and a second interlayer insulating layer in contact with at least a portion of sidewalls of the first source/drain contact. A lower surface of the second interlayer insulating layer may contact upper surfaces of the second gate electrode, the second source/drain contact, and the gate spacer between the second gate electrode and the second source/drain contact.

### CROSS-REFERENCE TO RELATED APPLICATION

This application claims priority from Korean Patent Application No. 10-2024-0074791 filed on Jun. 10, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device. For example, the present disclosure relates to a semiconductor device including a MBCFET™ (Multi-Bridge Channel Field Effect Transistor).

### 2. Description of the Related Art

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, they may be easier to scale. Additionally, the current control capability may be improved without increasing the gate length of the multi-gate transistor. Furthermore, the SCE (short channel effect), in which the potential of the channel region is influenced by the drain voltage, may be effectively limited and/or suppressed.

### SUMMARY

Aspects of the present disclosure provide a semiconductor device that limits and/or prevents shorts from occurring between source/drain contacts and gate electrodes by forming either the source/drain contact or the gate electrode at a lower height.

Furthermore, the aspects of the present disclosure also provide the semiconductor device that reduces interfacial resistance between the source/drain contacts and the wiring patterns and between the gate electrodes and the wiring patterns, respectively, by not forming separate vias between the source/drain contacts and the wiring patterns and between the gate electrodes and the wiring patterns, respectively.

The aspects of the present disclosure are not limited to those mentioned above and other aspects that are not mentioned above may be clearly understood by those skilled in the art from the description below.

According to some embodiments of the present disclosure, a semiconductor device may include a substrate; an active pattern extending in a first horizontal direction on the substrate; a first gate electrode, a second gate electrode, and a third gate electrode each extending in a second horizontal direction on the active pattern, the second horizontal direction being different from the first horizontal direction, and the first gate electrode, the second gate electrode, and the third gate electrode being sequentially spaced apart from each other in the first horizontal direction; a first source/drain region on the active pattern between the first gate electrode and the second gate electrode; a second source/drain region on the active pattern between the second gate electrode and the third gate electrode; a first source/drain contact extending in the second horizontal direction between the first gate electrode and the second gate electrode, the first source/drain contact electrically connected to the first source/drain region; a second source/drain contact extending in the second horizontal direction between the second gate electrode and the third gate electrode, the second source/drain contact electrically connected to the second source/drain region; a gate spacer extending in the second horizontal direction on both sidewalls of the second gate electrode in the first horizontal direction; a first interlayer insulating layer covering each of the first source/drain region and the second source/drain region; and a second interlayer insulating layer on the first interlayer insulating layer and in contact with at least a portion of sidewalls of the first source/drain contact in the second horizontal direction, the second interlayer insulating layer being a single layer. On the active pattern, a lower surface of the second interlayer insulating layer may be in contact with each of an upper surface of the second gate electrode, an upper surface of the second source/drain contact, and an upper surface of the gate spacer between the second gate electrode and the second source/drain contact.

According to some embodiments of the present disclosure, a semiconductor device may include a substrate; an active pattern extending in a first horizontal direction on the substrate; a plurality of nanosheets stacked and spaced apart from each other in a vertical direction on the active pattern; a gate electrode extending in a second horizontal direction on the active pattern, the second horizontal direction being different from the first horizontal direction, the gate electrode surrounding the plurality of nanosheets; a first source/drain region on a first side of the gate electrode on the active pattern; a second source/drain region on a second side of the gate electrode on the active pattern, the second side of the gate electrode being opposite the first side of the gate electrode in the first horizontal direction; a first source/drain contact extending in the second horizontal direction from the first side of the gate electrode, the first source/drain contact being electrically connected to the first source/drain region, the first source/drain contact including a contact barrier layer and a contact filler layer, the contact barrier layer forming a portion of sidewalls and a lower surface of the first source/drain contact, and the contact filling layer filling a space between portions of the contact barrier layer; a second source/drain contact extending in the second horizontal direction from the second side of the gate electrode, the second source/drain contact electrically connected to the second source/drain region; a gate spacer extending in the second horizontal direction on both sidewalls of the gate electrode in the first horizontal direction; a first interlayer insulating layer covering the first source/drain region and the second source/drain region; and a second interlayer insulating layer in contact with at least a portion of the sidewalls of the first source/drain contact in the second horizontal direction on the first interlayer insulating layer, the second interlayer insulating layer being in contact with at least a portion of sidewalls of the contact filling layer in the second horizontal direction, the second interlayer insulating layer being a single layer. An uppermost surface of the gate spacer between the first source/drain contact and the gate electrode on the active pattern may be higher than an upper surface of the gate spacer between the gate electrode and the second source/drain contact on the active pattern.

According to some embodiments of the present disclosure, a semiconductor device may include a substrate; a first active pattern extending in a first horizontal direction on the substrate; a second active pattern extending in the first horizontal direction on the substrate, the second active pattern spaced being apart from the first active pattern in a second horizontal direction, the second horizontal direction being different from the first horizontal direction; a first gate electrode, a second gate electrode and a third gate electrode each extending in the second horizontal direction on the first active pattern and the second active pattern, the first gate electrode, the second gate electrode, and the third gate electrode being sequentially spaced apart from each other in the first horizontal direction; a first source/drain region between the first gate electrode and the second gate electrode on the first active pattern; a second source/drain region between the second gate electrode and the third gate electrode on the first active pattern; a third source/drain region between the first gate electrode and the second gate electrode on the second active pattern; a fourth source/drain region between the second gate electrode and the third gate electrode on the second active pattern; a first source/drain contact extending in the second horizontal direction between the first gate electrode and the second gate electrode, the first source/drain contact electrically connected to each of the first source/drain region and the third source/drain region; a second source/drain contact extending in the second horizontal direction between the second gate electrode and the third gate electrode, the second source/drain contact electrically connected to each of the second source/drain region and the fourth source/drain region; a gate spacer extending in the second horizontal direction on both sidewalls of the second gate electrode in the first horizontal direction; a first interlayer insulating layer covering each of the first source/drain region, the second source/drain region, the third source/drain region, and the fourth source/drain region; and a second interlayer insulating layer in contact with at least a portion of sidewalls of the first source/drain contact in the second horizontal direction on the first interlayer insulating layer, the second interlayer insulating layer being a single layer. On the first active pattern, a lower surface of the second interlayer insulating layer may be in contact with each of an upper surface of the second gate electrode, an upper surface of the second source/drain contact, and an upper surface of the gate spacer between the second gate electrode and the second source/drain contact. On the second active pattern, the lower surface of the second interlayer insulating layer may be in contact with each of the upper surface of the second gate electrode, an upper surface of the first source/drain contact, and the upper surface of the gate spacer between the first source/drain contact and the second gate electrode. An uppermost surface of the gate spacer between the first source/drain contact and the second gate electrode on the first active pattern may be higher than the upper surface of the gate spacer between the second gate electrode and the second source/drain contact on the first active pattern. The upper surface of the gate spacer between the first source/drain contact and the second gate electrode on the second active pattern may be lower than the uppermost surface of the gate spacer between the second gate electrode and the second source/drain contact on the second active pattern.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout diagram for explaining a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIG. 5 is a cross-sectional view taken along line D-D′ of FIG. 1;

FIGS. 6 to 49 are intermediate stage diagrams for explaining methods of fabricating semiconductor devices according to some embodiments of the present disclosure;

FIGS. 50 to 51 are cross-sectional views for explaining semiconductor devices according to some other embodiments of the present disclosure;

FIGS. 52 to 53 are cross-sectional views for explaining semiconductor devices according to some other embodiments of the present disclosure;

FIGS. 54 and 55 are cross-sectional views for explaining semiconductor devices according to yet some other embodiments of the present disclosure;

FIG. 56 is a layout diagram for explaining a semiconductor device according to yet some other embodiments of the present disclosure; and

FIGS. 57 to 60 are cross-sectional views for explaining semiconductor devices according to other embodiments of the present disclosure.

### DETAILED DESCRIPTION OF THE EMBODIMENTS

In the following diagrams of the semiconductor device according to some embodiments, by way of example, the semiconductor device is described as including transistors (MBCFET™ (Multi-Bridge Channel Field Effect Transistor)) comprising nanosheets and fin-shaped transistors (FinFET) comprising a fin-shaped pattern channel region. However, the present disclosure is not limited thereto. In some other embodiments, the semiconductor device may include a tunneling transistor (tunneling FET), or a three-dimensional (3D) transistor. Additionally, the semiconductor device according to some other embodiments may include a bipolar junction transistor or a lateral double-diffused metal-oxide-semiconductor (LDMOS) transistor.

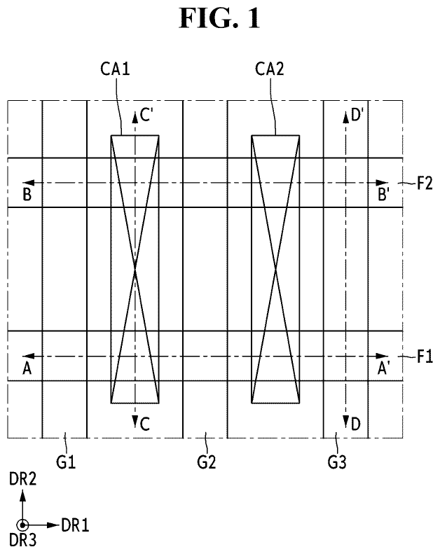

Hereinafter, the semiconductor device according to some embodiments of the present disclosure will be described with reference to FIGS. 1 to 5.

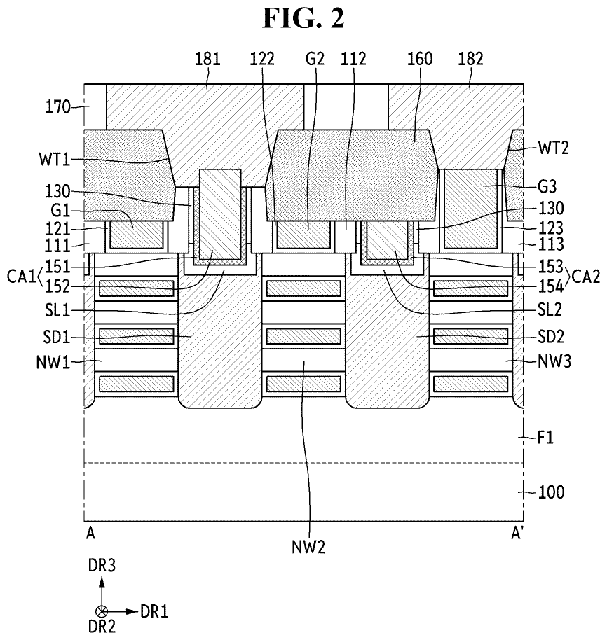

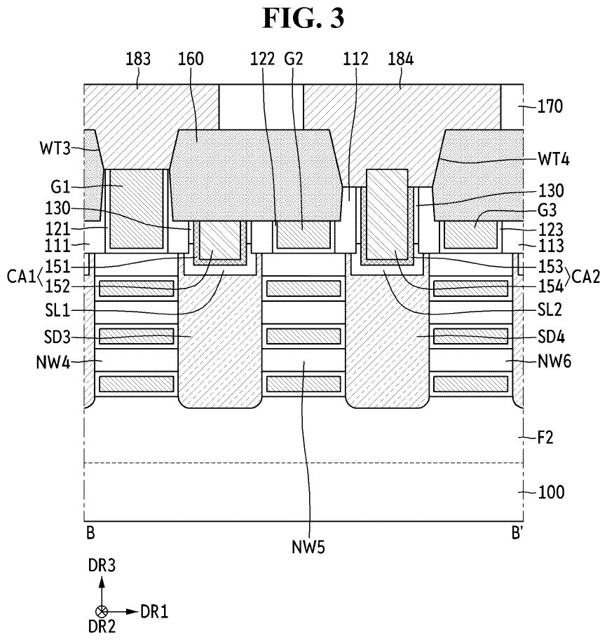

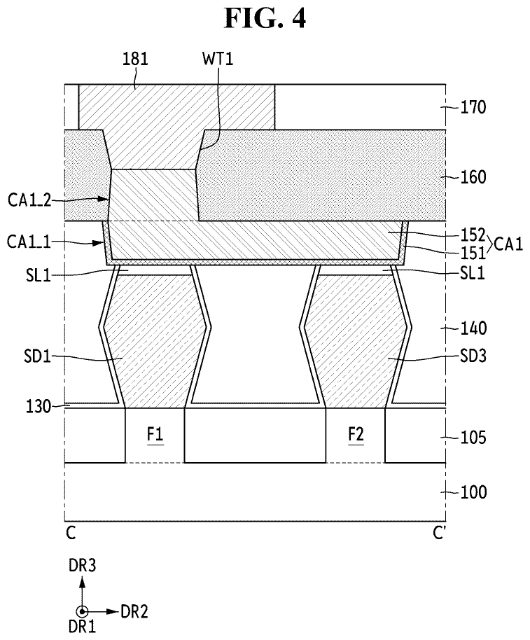

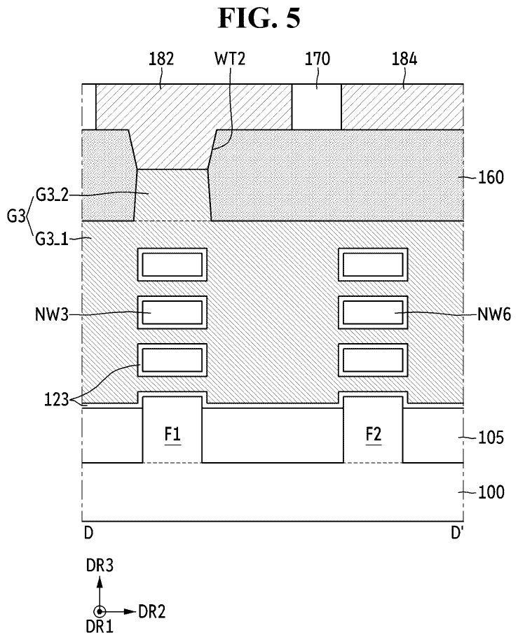

FIG. 1 is a layout diagram for explaining the semiconductor device according to some embodiments of the present disclosure. FIG. 2 is a cross-sectional view taken along the line A-A′ of FIG. 1. FIG. 3 is a cross-sectional view taken along the line B-B′ of FIG. 1. FIG. 4 is a cross-sectional view taken along the line C-C′ of FIG. 1. FIG. 5 is a cross-sectional view taken along the line D-D′ of FIG. 1.

Referring to FIGS. 1 to 5, the semiconductor device according to some embodiments of the present disclosure includes a substrate 100, first and second active patterns F1, F2, a field insulating layer 105, a first to sixth plurality of nanosheets NW1 to NW6, first to third gate electrodes G1, G2, G3, first to third gate spacers 111, 112, 113, first to third gate insulating layers 121, 122, 123, first to fourth source/drain regions SD1 to SD4, a first etch stop layer 130, a first interlayer insulating layer 140, first and second source/drain contacts CA1, CA2, first and second silicide layers SL1, SL2, a second interlayer insulating layer 160, a third interlayer insulating layer 170, and first to fourth wiring patterns 181 to 184.

The substrate 100 may be a silicon substrate or SOI (silicon-on-insulator). Alternatively, the substrate 100 may include silicon germanium, SGOI (silicon germanium on insulator), indium antimonide, lead telluride compounds, indium arsenide, indium phosphide, gallium arsenide, or gallium antimonide, but the present disclosure is not limited thereto.

Hereinafter, each of the first horizontal direction DR1 and the second horizontal direction DR2 may be defined as a direction parallel to an upper surface of the substrate 100. The second horizontal direction DR2 may be defined as a direction different from the first horizontal direction DR1. The vertical direction DR3 may be defined as a direction perpendicular to each of the first horizontal direction DR1 and the second horizontal direction DR2. That is, the vertical direction DR3 may be defined as a direction perpendicular to the upper surface of the substrate 100.

The first active pattern F1 may extend in the first horizontal direction DR1 on the substrate 100. The second active pattern F2 may extend in the first horizontal direction DR1 on the substrate 100. The second active pattern F2 may be spaced apart from the first active pattern F1 in the second horizontal direction DR2. Each of the first active pattern F1 and the second active pattern F2 may protrude from the upper surface of the substrate 100 in the vertical direction DR3. For example, each of the first active pattern F1 and the second active pattern F2 may be a portion of the substrate 100, or may include an epitaxial layer grown from the substrate 100.

The field insulating layer 105 may be disposed on the upper surface of the substrate 100. The field insulating layer 105 may surround the sidewall of each of the first active pattern F1 and the second active pattern F2. For example, the upper surface of each of the first active pattern F1 and the second active pattern F2 may protrude from the upper surface of the field insulating layer 105 in the vertical direction DR3. However, the present disclosure is not limited thereto. In some other embodiments, the upper surface of each of the first active pattern F1 and the second active pattern F2 may be formed on the same plane as the upper surface of the field insulating layer 105. The field insulating layer 105 may include, for example, an oxide layer, a nitride layer, an oxynitride layer, or a combination thereof.

Each of the first to third plurality of nanosheets NW1, NW2, NW3 may be disposed on the first active pattern F1. Each of the first to third plurality of nanosheets NW1, NW2, NW3 may include a plurality of nanosheets stacked and spaced apart from each other in the vertical direction DR3 on the first active pattern F1. The second plurality of nanosheets NW2 may be spaced apart from the first plurality of nanosheets NW1 in the first horizontal direction DR1. The third plurality of nanosheets NW3 may be spaced apart from the second plurality of nanosheets NW2 in the first horizontal direction DR1.

Each of the fourth to sixth plurality of nanosheets NW4, NW5, NW6 may be disposed on the second active pattern F2. Each of the fourth to sixth plurality of nanosheets NW4, NW5, NW6 may include a plurality of nanosheets stacked and spaced apart from each other in the vertical direction DR3 on the second active pattern F2. The fourth plurality of nanosheets NW4 may be spaced apart from the first plurality of nanosheets NW1 in the second horizontal direction DR2. The fifth plurality of nanosheets NW5 may be spaced apart from the fourth plurality of nanosheets NW4 in the first horizontal direction DR1. The fifth plurality of nanosheets NW5 may be spaced apart from the second plurality of nanosheets NW2 in the second horizontal direction DR2. The sixth plurality of nanosheets NW6 may be spaced apart from the fifth plurality of nanosheets NW5 in the first horizontal direction DR1. The sixth plurality of nanosheets NW6 may be spaced apart from the third plurality of nanosheets NW3 in the second horizontal direction DR2.

In FIGS. 2 and 3, each of the first to six plurality of nanosheets NW1 to NW6 is shown as including three nanosheets stacked and spaced apart from each other in the vertical direction DR3, but this is for convenience of explanation only and the present disclosure is not limited thereto. In some other embodiments, each of the first to six plurality of nanosheets NW1 to NW6 may include four or more nanosheets stacked and spaced apart from each other in the vertical direction DR3. For example, each of the first to six plurality of nanosheets NW1 to NW6 may include silicon (Si). However, the present disclosure is not limited thereto. In some other embodiments, each of the first to six plurality of nanosheets NW1 to NW6 may include silicon germanium (SiGe).

Each of the first to third gate electrodes G1, G2, G3 may extend in the second horizontal direction DR2 on the first active pattern F1, the second active pattern F2, and the field insulating layer 105. The second gate electrode G2 may be spaced apart from the first gate electrode G1 in the first horizontal direction DR1. The third gate electrode G3 may be spaced apart from the second gate electrode G2 in the first horizontal direction DR1. The first gate electrode G1 may surround each of the first plurality of nanosheets NW1 and the fourth plurality of nanosheets NW4. The second gate electrode G2 may surround each of the second plurality of nanosheets NW2 and the fifth plurality of nanosheets NW5. The third gate electrode G3 may surround each of the third plurality of nanosheets NW3 and the sixth plurality of nanosheets NW6.

For example, on the first active pattern F1, the upper surface of the third gate electrode G3 may be formed higher than each of the upper surface of the first gate electrode G1 and the upper surface of the second gate electrode G2. For example, on the second active pattern F2, the upper surface of the first gate electrode G1 may be formed higher than each of the upper surface of the second gate electrode G2 and the upper surface of the third gate electrode G3. For example, the third gate electrode G3 may include a first portion G3_1 and a second portion G3_2 disposed on the first portion G3_1. For example, the first portion G3_1 of the third gate electrode G3 may extend in the second horizontal direction DR2 on the first active pattern F1, the second active pattern F2, and the field insulating layer 105. The first portion G3_1 of the third gate electrode G3 may surround each of the third plurality of nanosheets NW3 and the sixth plurality of nanosheets NW6.

For example, the second portion G3_2 of the third gate electrode G3 may protrude in the vertical direction DR3 from the first portion G3_1 of the third gate electrode G3. For example, the width of the second portion G3_2 of the third gate electrode G3 in the second horizontal direction DR2 may be smaller than the width of the first portion G3_1 of the third gate electrode G3 in the second horizontal direction DR2. For example, the width of the second portion G3_2 of the third gate electrode G3 in the first horizontal direction DR1 may be the same as the width of the first portion G3_1 of the third gate electrode G3 in the first horizontal direction DR1. For example, the second portion G3_2 of the third gate electrode G3 may overlap with the first active pattern F1 in the vertical direction DR3. However, the present disclosure is not limited thereto. In some other embodiments, the second portion G3_2 of the third gate electrode G3 may overlap with the field insulating layer 105 in the vertical direction DR3.

Each of the first to third gate electrodes G1, G2, G3 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAlC—N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. Each of the first to third gate electrodes G1, G2, G3 may also include conductive metal oxides, conductive metal oxynitrides, and the like, and may include the aforementioned materials in their oxidized forms.

The first source/drain region SD1 may be disposed between the first gate electrode G1 and the second gate electrode G2 on the first active pattern F1. The first source/drain region SD1 may be in contact with the sidewall of each of the first and second plurality of nanosheets NW1, NW2 in the first horizontal direction DR1. The second source/drain region SD2 may be disposed between the second gate electrode G2 and the third gate electrode G3 on the first active pattern F1. The second source/drain region SD2 may be in contact with the sidewall of each of the second and third plurality of nanosheets NW2, NW3 in the first horizontal direction DR1. The third source/drain region SD3 may be disposed between the first gate electrode G1 and the second gate electrode G2 on the second active pattern F2. The third source/drain region SD3 may be in contact with the sidewall of each of the fourth and fifth plurality of nanosheets NW4, NW5 in the first horizontal direction DR1. The fourth source/drain region SD4 may be disposed between the second gate electrode G2 and the third gate electrode G3 on the second active pattern F2. The fourth source/drain region SD4 may be in contact with the sidewall of each of the fifth and sixth plurality of nanosheets NW5, NW6 in the first horizontal direction DR1.

The first gate spacer 111 may extend in the second horizontal direction DR2 along both sidewalls of the first gate electrode G1 on the upper surface of the uppermost nanosheet of the first plurality of nanosheets NW1, the upper surface of the uppermost nanosheet of the fourth plurality of nanosheets NW4, and the field insulating layer 105. The second gate spacer 112 may extend in the second horizontal direction DR2 along both sidewalls of the second gate electrode G2 on the upper surface of the uppermost nanosheet of the second plurality of nanosheets NW2, the upper surface of the uppermost nanosheet of the fifth plurality of nanosheets NW5, and the field insulating layer 105. The third gate spacer 113 may extend in the second horizontal direction DR2 along both sidewalls of the third gate electrode G3 on the upper surface of the uppermost nanosheet of the third plurality of nanosheets NW3, the upper surface of the uppermost nanosheet of the sixth plurality of nanosheets NW6, and the field insulating layer 105. Each of the first to third gate spacers 111, 112, 113 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. However, the present disclosure is not limited thereto.

The first gate insulating layer 121 may be disposed between the first gate electrode G1 and the first gate spacer 111. The first gate insulating layer 121 may be disposed between the first gate electrode G1 and each of the first and third source/drain regions SD1, SD3. The first gate insulating layer 121 may be disposed between the first gate electrode G1 and each of the first and second active patterns F1, F2. The first gate insulating layer 121 may be disposed between the first gate electrode G1 and the field insulating layer 105. The first gate insulating layer 121 may be disposed between the first gate electrode G1 and each of the first and fourth plurality of nanosheets NW1, NW4.

The second gate insulating layer 122 may be disposed between the second gate electrode G2 and the second gate spacer 112. The second gate insulating layer 122 may be disposed between the second gate electrode G2 and each of the first to fourth source/drain regions SD1 to SD4. The second gate insulating layer 122 may be disposed between the second gate electrode G2 and each of the first and second active patterns F1 and F2. The second gate insulating layer 122 may be disposed between the second gate electrode G2 and the field insulating layer 105. The second gate insulating layer 122 may be disposed between the second gate electrode G2 and each of the second and fifth plurality of nanosheets NW2, NW5.

The third gate insulating layer 123 may be disposed between the third gate electrode G3 and the third gate spacer 113. The third gate insulating layer 123 may be disposed between the third gate electrode G3 and each of the second and fourth source/drain regions SD2, SD4. The third gate insulating layer 123 may be disposed between the third gate electrode G3 and each of the first and second active patterns F1, F2. The third gate insulating layer 123 may be disposed between the third gate electrode G3 and the field insulating layer 105. The third gate insulating layer 123 may be disposed between the third gate electrode G3 and each of the third and sixth plurality of nanosheets NW3, NW6.

Each of the first to third gate insulating layers 121, 122, 123 may include at least one of silicon oxide, silicon oxynitride, silicon nitride, or a high-k material having a dielectric constant greater than that of silicon oxide. The high-k material may include, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some other embodiments may include a NC (Negative Capacitance) FET utilizing a negative capacitor. For example, each of the first to third gate insulating layers 121, 122, 123 may include a ferroelectric material layer with ferroelectric properties and a paraelectric material layer with paraelectric properties.

The ferroelectric material layer may have a negative capacitance, while the paraelectric material layer may have a positive capacitance. For example, if two or more capacitors are connected in series and each capacitor has a positive capacitance, the total capacitance may be less than the capacitance of each individual capacitor. On the other hand, if at least one of the capacitances of the two or more capacitors connected in series has a negative value, the total capacitance may have a positive value and be greater than the absolute value of each individual capacitance.

When the ferroelectric material layer with a negative capacitance and the paraelectric material layer with a positive capacitance are connected in series, the total capacitance value of the ferroelectric material layer and the paraelectric material layer connected in series may be increased. By utilizing the increase in total capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. In another example, hafnium zirconium oxide may be a material in which zirconium (Zr) is doped into hafnium oxide. In another example, hafnium zirconium oxide may be a compound of hafnium (Hf), zirconium (Zr), and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer includes, the type of dopant included in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

If the dopant is aluminum (Al), the ferroelectric material layer may include 3 to 8 at % (atomic %) of aluminum. Here, the ratio of the dopant may be a ratio of aluminum to the sum of hafnium and aluminum.

If the dopant is silicon (Si), the ferroelectric material layer may include 2 to 10 at % of silicon. If the dopant is yttrium (Y), the ferroelectric material layer may include 2 to 10 at % of yttrium. If the dopant is gadolinium (Gd), the ferroelectric material layer may include 1 to 7 at % of gadolinium. If the dopant is zirconium (Zr), the ferroelectric material layer may include 50 to 80 at % of zirconium.

The paraelectric material layer may have paraelectric properties. The paraelectric material layer may include, for example, at least one of silicon oxide and a high-k metal oxide. The metal oxide included in the paraelectric material layer may include, for example, at least one of hafnium oxide, zirconium oxide, and aluminum oxide, but is not limited thereto.

The ferroelectric material layer and the paraelectric material layer may include the same material. The ferroelectric material layer may have ferroelectric properties, while the paraelectric material layer may not have ferroelectric properties. For example, if the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Since each ferroelectric material may have a different critical thickness that exhibits ferroelectric properties, the thickness of the ferroelectric material layer may vary depending on the specific ferroelectric material.

In one example, each of the first to third gate insulating layers 121, 122, 123 may include a single ferroelectric material layer. In another example, each of the first to third gate insulating layers 121, 122, 123 may include a plurality of ferroelectric material layers spaced apart from each other. Each of the first to third gate insulating layers 121, 122, 123 may have a stacked layer structure in which the plurality of ferroelectric material layers and the plurality of paraelectric material layers are alternately stacked.

The first etch stop layer 130 may be disposed on the upper surface of the field insulating layer 105. The first etch stop layer 130 may be disposed on the sidewall of each of the first to third gate spacers 111, 112, 113. The first etch stop layer 130 may be disposed on the sidewall of each of the first to fourth source/drain regions SD1 to SD4 in the second horizontal direction DR2. For example, the first etch stop layer 130 may be formed conformally. For example, the first etch stop layer 130 may include at least one of aluminum oxide, aluminum nitride, hafnium oxide, zirconium oxide, silicon oxide, silicon nitride, silicon oxynitride, and a low-k material.

The first interlayer insulating layer 140 may be disposed on the first etch stop layer 130. For example, the first interlayer insulating layer 140 may cover each of the first to fourth source/drain regions SD1 to SD4. For example, the first interlayer insulating layer 140 may include at least one of silicon oxide, silicon nitride, silicon oxynitride, and a low-k material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, but the present disclosure is not limited thereto.

The first source/drain contact CA1 may extend in the second horizontal direction DR2 between the first gate electrode G1 and the second gate electrode G2. The first source/drain contact CA1 may be disposed on the upper portion of each of the first source/drain region SD1 and the third source/drain region SD3. The first source/drain contact CA1 may be electrically connected to each of the first source/drain region SD1 and the third source/drain region SD3. For example, at least a portion of the first source/drain contact CA1 may be disposed inside of the first interlayer insulating layer 140. For example, both sidewalls of the first source/drain contact CA1 in the first horizontal direction DR1 may be in contact with the first etch stop layer 130. For example, both sidewalls of the first source/drain contact CA1 in the second horizontal direction DR2 may be in contact with each of the first interlayer insulating layer 140 and the second interlayer insulating layer 160. For example, the uppermost surface of the first source/drain contact CA1 disposed on the first active pattern F1 may be formed higher than the upper surface of the first source/drain contact CA1 disposed on the second active pattern F2.

For example, the first source/drain contact CA1 may include a first portion CA1_1 and a second portion CA1_2 disposed on the first portion CA1_1. For example, the first portion CA1_1 of the first source/drain contact CA1 may extend in the second horizontal direction DR2 from the upper portion of each of the first and third source/drain regions SD1, SD3. For example, both sidewalls of the first portion CA1_1 of the first source/drain contact CA1 in the second horizontal direction DR2 may be in contact with the first interlayer insulating layer 140. For example, the upper surface of the first portion CA1_1 of the first source/drain contact CA1 may be formed on the same plane as the upper surface of the first interlayer insulating layer 140.

For example, the second portion CA1_2 of the first source/drain contact CA1 may protrude from the first portion CA1_1 of the first source/drain contact CA1 in the vertical direction DR3. For example, the width of the second portion CA1_2 of the first source/drain contact CA1 in the second horizontal direction DR2 may be smaller than the width of the first portion CA1_1 of the first source/drain contact CA1 in the second horizontal direction DR2. For example, the width of the second portion CA1_2 of the first source/drain contact CA1 in the first horizontal direction DR1 may be the same as the width of the first portion CA1_1 of the first source/drain contact CA1 in the first horizontal direction DR1. For example, the second portion CA1_2 of the first source/drain contact CA1 may overlap the first active pattern F1 in the vertical direction DR3. However, the present disclosure is not limited thereto. In some other embodiments, the second portion CA1_2 of the first source/drain contact CA1 may overlap the field insulating layer 105 in the vertical direction DR3.

For example, the first source/drain contact CA1 may include a first contact barrier layer 151 and a first contact filling layer 152. For example, the first contact barrier layer 151 may form a portion of the sidewalls and the lower surface of the first source/drain contact CA1. For example, the first contact filling layer 152 may fill the space between the first contact barrier layer 151. For example, the first contact barrier layer 151 may form the sidewalls and the lower surface of the first portion CA1_1 of the first source/drain contact CA1. For example, the first contact barrier layer 151 may not be disposed on both sidewalls of the first contact filling layer 152 of the second portion CA1_2 of the first source/drain contact CA1 in the second horizontal direction DR2. For example, the sidewalls of the first contact barrier layer 151 in the first horizontal direction DR1 may be in contact with the first etch stop layer 130. The sidewalls of the first contact barrier layer 151 in the second horizontal direction DR2 may be in contact with the first interlayer insulating layer 140.

For example, the uppermost surface of the first contact filling layer 152 may be formed higher than the uppermost surface of the first contact barrier layer 151 on the first active pattern F1. For example, the upper surface of the first contact filling layer 152 may be formed on the same plane as the upper surface of the first contact barrier layer 151 on the second active pattern F2. Each of the first contact barrier layer 151 and the first contact filling layer 152 may include a conductive material. For example, the first contact barrier layer 151 may include at least one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), and rhodium (Rh). For example, the first contact filling layer 152 may include at least one of aluminum (Al), tungsten (W), cobalt (Co), ruthenium (Ru), and molybdenum (Mo).

The second source/drain contact CA2 may extend in a second horizontal direction DR2 between the second gate electrode G2 and the third gate electrode G3. The second source/drain contact CA2 may be disposed on the upper portion of each of the second source/drain region SD2 and the fourth source/drain region SD4. The second source/drain contact CA2 may be electrically connected to each of the second source/drain region SD2 and the fourth source/drain region SD4. Although not shown, for example, at least a portion of the second source/drain contacts CA2 may be disposed inside of the first interlayer insulating layer 140. For example, both sidewalls of the second source/drain contact CA2 in the first horizontal direction DR1 may be in contact with the first etch stop layer 130. Although not shown, for example, both sidewalls of the second source/drain contact CA2 in the second horizontal direction DR2 may be in contact with each of the first interlayer insulating layer 140 and the second interlayer insulating layer 160.

For example, the second source/drain contact CA2 may have a similar shape to the first source/drain contact CA1. However, while the first source/drain contact CA1 may be formed with a protruding portion in the vertical direction DR3 on the first active pattern F1, the second source/drain contact CA2 may be formed with a protruding portion in the vertical direction DR3 on the second active pattern F2. For example, the uppermost surface of the second source/drain contact CA2 disposed on the first active pattern F1 may be formed lower than the upper surface of the second source/drain contact CA2 disposed on the second active pattern F2. For example, the upper surface of the second source/drain contact CA2 on the first active pattern F1 may be formed lower than the uppermost surface of the first source/drain contact CA1. For example, the uppermost surface of the second source/drain contact CA2 on the second active pattern F2 may be formed higher than the upper surface of the first source/drain contact CA1.

For example, the second source/drain contact CA2 may include a second contact barrier layer 153 and a second contact filling layer 154. For example, the second contact barrier layer 153 may form a portion of the sidewalls and the lower surface of the second source/drain contact CA2. For example, the second contact filling layer 154 may fill the space between the second contact barrier layer 153. Although not shown, for example, on the second active pattern F2, the second contact barrier layer 153 is not disposed on both sidewalls in the second horizontal direction DR2 of the protruding portion of the second source/drain contact CA2 in the vertical direction DR3. For example, the sidewall of the second contact barrier layer 153 in the first horizontal direction DR1 may be in contact with the first etch stop layer 130. Although not shown, the sidewall of the second contact barrier layer 153 in the second horizontal direction DR2 may be in contact with the first interlayer insulating layer 140.

For example, on the first active pattern F1, the upper surface of the second contact filling layer 154 may be formed on the same plane as the upper surface of the second contact barrier layer 153. For example, on the second active pattern F2, the uppermost surface of the second contact filling layer 154 may be formed higher than the upper surface of the second contact barrier layer 153. Each of the second contact barrier layer 153 and the second contact filling layer 154 may include a conductive material. For example, the second contact barrier layer 153 may include the same material as the first contact barrier layer 151. Additionally, the second contact filling layer 154 may include the same material as the first contact filling layer 152.

For example, the uppermost surface of the second gate spacer 112 disposed between the first source/drain contact CA1 and the second gate electrode G2 on the first active pattern F1 may be formed higher than the upper surface of the second gate spacer 112 disposed between the second gate electrode G2 and the second source/drain contact CA2 on the first active pattern F1. For example, the upper surface of the second gate spacer 112 disposed between the second gate electrode G2 and the second source/drain contact CA2 on the first active pattern F1 may be formed on the same plane as the upper surface of the second gate electrode G2 disposed on the first active pattern F1. For example, on the first active pattern F1, the upper surface of the second source/drain contact CA2 may be formed on the same plane as each of the upper surface of the first gate electrode G1 and the upper surface of the second gate electrode G2.

For example, the upper surface of the second gate spacer 112 disposed between the first source/drain contact CA1 and the second gate electrode G2 on the second active pattern F2 may be formed lower than the uppermost surface of the second gate spacer 112 disposed between the second gate electrode G2 and the second source/drain contact CA2 on the second active pattern F2. For example, the upper surface of the second gate spacer 112 disposed between the first source/drain contact CA1 and the second gate electrode G2 on the second active pattern F2 may be formed on the same plane as the upper surface of the second gate electrode G2 disposed on the second active pattern F2. For example, on the second active pattern F2, the upper surface of the first source/drain contact CA1 may be formed on the same plane as each of the upper surface of the second gate electrode G2 and the upper surface of the third gate electrode G3.

The first silicide layer SL1 may be disposed along the interface between each of the first and third source/drain regions SD1, SD3 and the first source/drain contact CA1. The second silicide layer SL2 may be disposed along the interface between each of the second and fourth source/drain regions SD2, SD4 and the second source/drain contact CA2. For example, each of the first and second silicide layers SL1, SL2 may include a metal silicide material.

The second interlayer insulating layer 160 may be disposed on the upper surface of the first interlayer insulating layer 140. For example, the second interlayer insulating layer 160 may be in contact with the upper surface of the first interlayer insulating layer 140. For example, the lower surface of the second interlayer insulating layer 160 may be formed lower than each of the uppermost surface of the first gate electrode G1 and the uppermost surface of the third gate electrode G3. For example, the lower surface of the second interlayer insulating layer 160 may be formed lower than the uppermost surface of each of the first and second source/drain contacts CA1, CA2. For example, the upper surface of the second interlayer insulating layer 160 may be formed higher than each of the uppermost surface of the first gate electrode G1 and the uppermost surface of the third gate electrode G3. For example, the upper surface of the second interlayer insulating layer 160 may be formed higher than the uppermost surface of each of the first and second source/drain contacts CA1, CA2.

For example, the second interlayer insulating layer 160 may be in contact with a portion of the upper surface of the first portion CA1_1 of the first source/drain contact CA1. Further, the second interlayer insulating layer 160 may be in contact with both sidewalls of the second portion CA1_2 of the first source/drain contact CA1 in the second horizontal direction DR2. For example, the second interlayer insulating layer 160 may be in contact with a portion of the upper surface of the first portion G3_1 of the third gate electrode G3. Further, the second interlayer insulating layer 160 may be in contact with both sidewalls of the second portion G3_2 of the third gate electrode G3 in the second horizontal direction DR2.

For example, on the first active pattern F1, the lower surface of the second interlayer insulating layer 160 may be in contact with each of the first gate spacer 111, the upper surface of the first gate electrode G1, the upper surface of the second gate electrode G2, the upper surface of the second source/drain contact CA2, and the third gate spacer 113. For example, on the first active pattern F1, the lower surface of the second interlayer insulating layer 160 may be in contact with the upper surface of the second gate spacer 112 disposed between the second gate electrode G2 and the second source/drain contact CA2. For example, on the second active pattern F2, the lower surface of the second interlayer insulating layer 160 may be in contact with each of the first gate spacer 111, the upper surface of the first source/drain contact CA1, the upper surface of the second gate electrode G2, the upper surface of the third gate electrode G3, and the third gate spacer 113. For example, on the second active pattern F2, the lower surface of the second interlayer insulating layer 160 may be in contact with the upper surface of the second gate spacer 112 disposed between the first source/drain contact CA1 and the second gate electrode G2.

For example, on the first active pattern F1, the second interlayer insulating layer 160 is not disposed on each of the upper surface of the first source/drain contact CA1 and the upper surface of the third gate electrode G3. Further, on the second active pattern F2, the second interlayer insulating layer 160 is not disposed on each of the upper surface of the first gate electrode G1 and the upper surface of the second source/drain contact CA2. For example, on the first active pattern F1, the slope profile of the sidewalls of the second interlayer insulating layer 160 may be formed differently based on the uppermost surface of the first contact barrier layer 151. Further, on the first active pattern F1, the slope profile of the sidewalls of the second interlayer insulating layer 160 may be formed differently based on the upper surface of the third gate electrode G3. For example, on the second active pattern F2, the slope profile of the sidewalls of the second interlayer insulating layer 160 may be formed differently based on the upper surface of the first gate electrode G1. Additionally, on the second active pattern F2, the slope profile of the sidewalls of the second interlayer insulating layer 160 may be formed differently based on the uppermost surface of the second contact barrier layer 153.

For example, the second interlayer insulating layer 160 may be formed as a single layer. The second interlayer insulating layer 160 may include an insulating material. For example, the second interlayer insulating layer 160 may include any one of silicon nitride (SiN), silicon oxynitride (SiON), silicon carbonitride (SiCN), silicon oxide (SiO₂), silicon oxycarbonitride (SiOCN), and silicon oxide (SiOC), although the present disclosure are not limited thereto. For example, the second interlayer insulating layer 160 may include a different material from the first interlayer insulating layer 140. However, the present disclosure is not limited thereto.

The first wiring trench WT1 may be formed inside the second interlayer insulating layer 160. The sidewalls of the first wiring trench WT1 may be defined by the second interlayer insulating layer 160. The first wiring trench WT1 may be formed on the upper surface of the second portion CA1_2 of the first source/drain contact CA1 on the first active pattern F1. For example, the bottom surface of the first wiring trench WT1 may be defined by the upper surface of the first etch stop layer 130, the upper surface of the first contact barrier layer 151, a portion of the sidewall and the upper surface of the first contact filling layer 152. Further, the bottom surface of the first wiring trench WT1 may be defined by the upper surface of each of the first and second gate spacers 111, 112 adjacent the first source/drain contact CA1. For example, as the first wiring trench WT1 gets closer to the upper surface of the second interlayer insulating layer 160, the width of the first wiring trench WT1 in the first horizontal direction DR1 may increase sequentially. Furthermore, as the first wiring trench WT1 gets closer to the upper surface of the second interlayer insulating layer 160, the width of the second horizontal direction DR2 of the first wiring trench WT1 may increase sequentially.

The second wiring trench WT2 may be formed inside the second interlayer insulating layer 160. The sidewalls of the second wiring trench WT2 may be defined by the second interlayer insulating layer 160. The second wiring trench WT2 may be formed on the upper surface of the second portion G3_2 of the third gate electrode G3 on the first active pattern F1. For example, the bottom surface of the second wiring trench WT2 may be defined by the upper surface of the third gate insulating layer 123 and the upper surface of the third gate electrode G3. For example, as the second wiring trench WT2 gets closer to the upper surface of the second interlayer insulating layer 160, the width of the second wiring trench WT2 in the first horizontal direction DR1 may increase sequentially. Furthermore, as the second wiring trench WT2 gets closer to the upper surface of the second interlayer insulating layer 160, the width of the second wiring trench WT2 in the second horizontal direction DR2 may increase sequentially.

The third wiring trench WT3 may be formed inside the second interlayer insulating layer 160. The sidewalls of the third wiring trench WT3 may be defined by the second interlayer insulating layer 160. The third wiring trench WT3 may be formed on the upper surface of the protruding portion of the first gate electrode G1 in the vertical direction DR3 on the second active pattern F2. For example, the bottom surface of the third wiring trench WT3 may be defined by the upper surface of the first gate insulating layer 121 and the upper surface of the first gate electrode G1. For example, as the third wiring trench WT3 gets closer to the upper surface of the second interlayer insulating layer 160, the width of the third wiring trench WT3 in the first horizontal direction DR1 may increase sequentially. Although not shown, as the third wiring trench WT3 gets closer to the upper surface of the second interlayer insulating layer 160, the width of the third wiring trench WT3 in the second horizontal direction DR2 may also increase sequentially.

The fourth wiring trench WT4 may be formed inside the second interlayer insulating layer 160. The sidewalls of the fourth wiring trench WT4 may be defined by the second interlayer insulating layer 160. The fourth wiring trench WT4 may be formed on the upper surface of the protruding portion of the second source/drain contact CA2 in the vertical direction DR3 on the second active pattern F2. For example, the bottom surface of the fourth wiring trench WT4 may be defined by the upper surface of the first etch stop layer 130, the upper surface of the second contact barrier layer 153, the portion of the sidewall and the upper surface of the second contact filling layer 154. Further, the bottom surface of the fourth wiring trench WT4 may be defined by the upper surface of each of the second and third gate spacers 112, 113 adjacent to the second source/drain contact CA2. For example, as the fourth wiring trench WT4 gets closer to the upper surface of the second interlayer insulating layer 160, the width of the fourth wiring trench WT4 in the first horizontal direction DR1 may increase sequentially. Also, although not shown, as the fourth wiring trench WT4 gets closer to the upper surface of the second interlayer insulating layer 160, the width of the fourth wiring trench WT4 in the second horizontal direction DR2 may increase sequentially.

The first wiring pattern 181 may fill the inside of the first wiring trench WT1. Additionally, the first wiring pattern 181 may be formed on the upper surface of the second interlayer insulating layer 160 adjacent to the first wiring trench WT1. The first wiring pattern 181 may be in contact with the upper surface of the second interlayer insulating layer 160 adjacent to the first wiring trench WT1. For example, the first wiring pattern 181 may be formed integrally. For example, inside the first wiring trench WT1, the first wiring pattern 181 may be in contact with the upper surface of the first source/drain contact CA1. For example, inside the first wiring trench WT1, the first wiring pattern 181 may be in contact with each of the upper surface of the first contact barrier layer 151 and the upper surface of the first contact filling layer 152. Inside the first wiring trench WT1, the first wiring pattern 181 may be in contact with the sidewall of the first contact filling layer 152 on the upper surface of the first contact barrier layer 151. Inside the first wiring trench WT1, the first wiring pattern 181 may be in contact with each of the upper surface of the first etch stop layer 130, the upper surface of the first gate spacer 111, and the upper surface of the second gate spacer 112. The first wiring pattern 181 may be electrically connected to the first source/drain contact CA1.

The second wiring pattern 182 may fill the inside of the second wiring trench WT2. Additionally, the second wiring pattern 182 may be formed on the upper surface of the second interlayer insulating layer 160 adjacent to the second wiring trench WT2. The second wiring pattern 182 may be in contact with the upper surface of the second interlayer insulating layer 160 adjacent to the second wiring trench WT2. For example, the second wiring pattern 182 may be formed integrally. For example, inside the second wiring trench WT2, the second wiring pattern 182 may be in contact with each of the upper surface of the third gate electrode G3 and the upper surface of the third gate insulating layer 123. The second wiring pattern 182 may be electrically connected to the third gate electrode G3.

The third wiring pattern 183 may fill the inside of the third wiring trench WT3. Additionally, the third wiring pattern 183 may be formed on the upper surface of the second interlayer insulating layer 160 adjacent to the third wiring trench WT3. The third wiring pattern 183 may be in contact with the upper surface of the second interlayer insulating layer 160 adjacent to the third wiring trench WT3. For example, the third wiring pattern 183 may be formed integrally. For example, inside the third wiring trench WT3, the third wiring pattern 183 may be in contact with each of the upper surface of the first gate electrode G1 and the upper surface of the first gate insulating layer 12. The third wiring pattern 183 may be electrically connected to the first gate electrode G1.

The fourth wiring pattern 184 may fill the inside of the fourth wiring trench WT4. Additionally, the fourth wiring pattern 184 may be formed on the upper surface of the second interlayer insulating layer 160 adjacent to the fourth wiring trench WT4. The fourth wiring pattern 184 may be in contact with the upper surface of the second interlayer insulating layer 160 adjacent to the fourth wiring trench WT4. For example, the fourth wiring pattern 184 may be formed integrally. For example, inside the fourth wiring trench WT4, the fourth wiring pattern 184 may be in contact with the upper surface of the second source/drain contact CA2. For example, inside the fourth wiring trench WT4, the fourth wiring pattern 184 may be in contact with each of the upper surface of the second contact barrier layer 153 and the upper surface of the second contact filling layer 154. Inside the fourth wiring trench WT4, the fourth wiring pattern 184 may be in contact with the sidewall of the second contact filling layer 154 on the upper surface of the second contact barrier layer 153. Inside the fourth wiring trench WT4, the fourth wiring pattern 184 may be in contact with each of the upper surface of the first etch stop layer 130, the upper surface of the second gate spacer 112, and the upper surface of the third gate spacer 113. The fourth wiring pattern 184 may be electrically connected to the second source/drain contact CA2.

The third interlayer insulating layer 170 may be disposed on the upper surface of the second interlayer insulating layer 160. The third interlayer insulating layer 170 may surround the sidewall of each of the first to fourth wiring patterns 181 to 184. The third interlayer insulating layer 170 may include an insulating material. For example, the third interlayer insulating layer 170 may include at least one of silicon oxide, silicon nitride, silicon oxynitride, and a low-k material.

In the semiconductor device according to some embodiments of the present disclosure, the height of the upper surface of each of the first and second gate electrodes G1, G2 disposed on both sides of the first source/drain contact CA1 in the first horizontal direction DR1 on the first active pattern F1 may be formed lower than the height of the upper surface of the first source/drain contact CA1. Accordingly, short may be limited and/or prevented from occurring between the first source/drain contact CA1 and each of the first and second gate electrodes G1, G2. Furthermore, in the semiconductor device according to some embodiments of the present disclosure, the height of the upper surface of the second source/drain contact CA2 disposed on one side of the third gate electrode G3 in the first horizontal direction DR1 on the first active pattern F1 may be formed lower than the height of the upper surface of the third gate electrode G3. As a result, short may be limited and/or prevented from occurring between the third gate electrode G3 and the second source/drain contact CA2.

In the semiconductor device according to some embodiments of the present disclosure, the first wiring pattern 181 formed inside the second interlayer insulating layer 160 may be directly connected to the first source/drain contact CA1. That is, a separate via connecting the first source/drain contact CA1 and the first wiring pattern 181 is not disposed. Accordingly, the interfacial resistance between the first source/drain contact CA1 and the first wiring pattern 181 may be reduced. Additionally, in the semiconductor device according to some embodiments of the present disclosure, the second wiring pattern 182 formed inside of the second interlayer insulating layer 160 may be directly connected to the third gate electrode G3. That is, a separate via connecting the third gate electrode G3 and the second wiring pattern 182 is not disposed. Accordingly, the interfacial resistance between the third gate electrode G3 and the second wiring pattern 182 may be reduced.

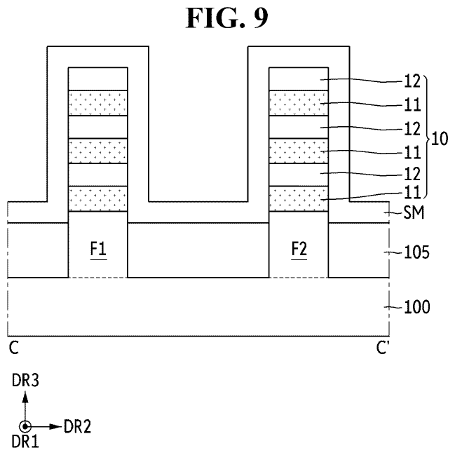

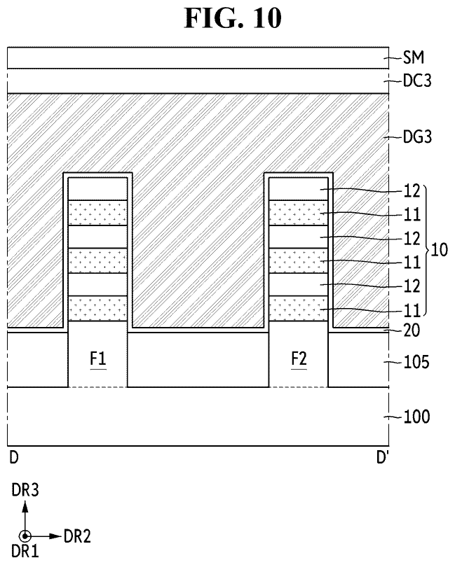

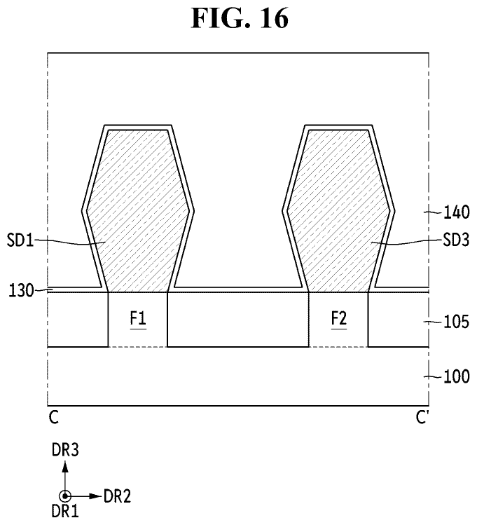

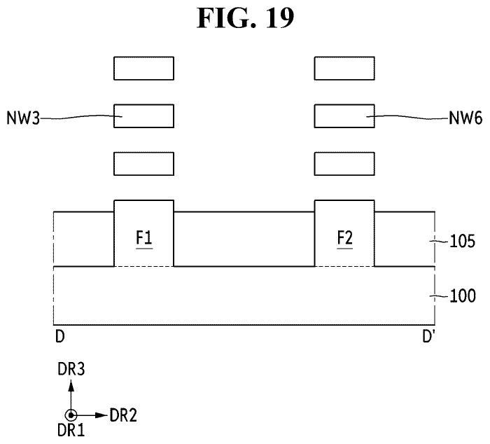

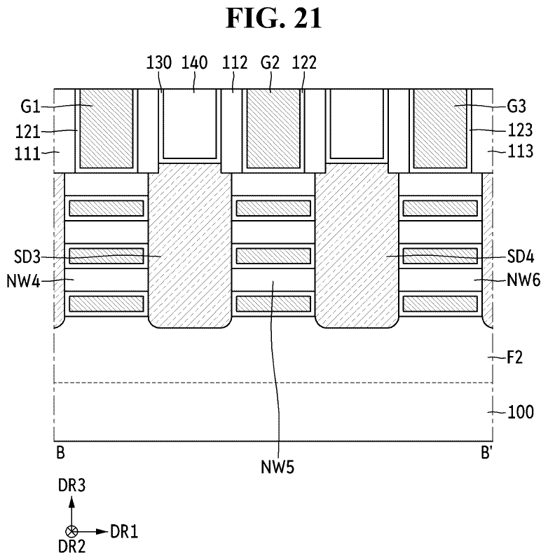

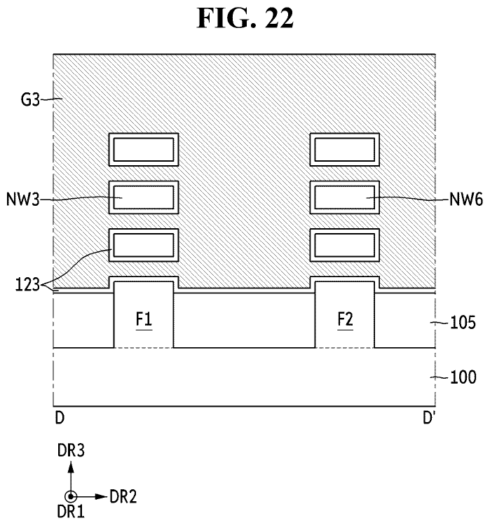

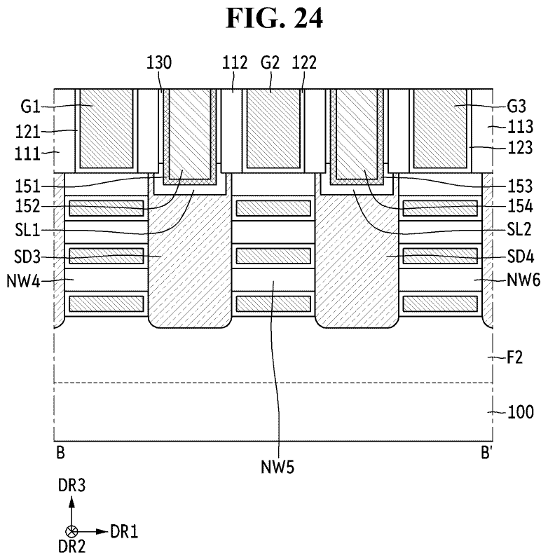

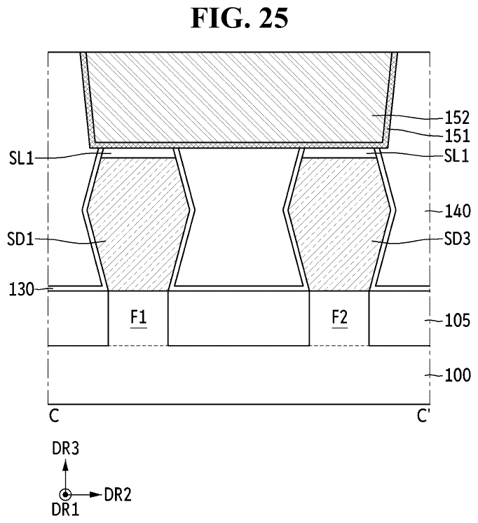

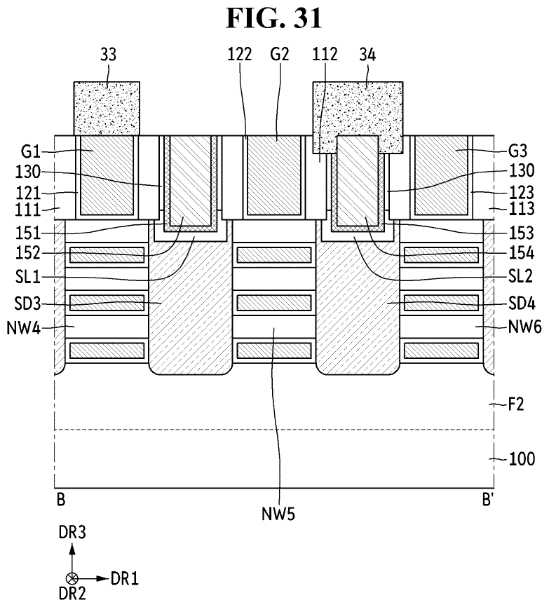

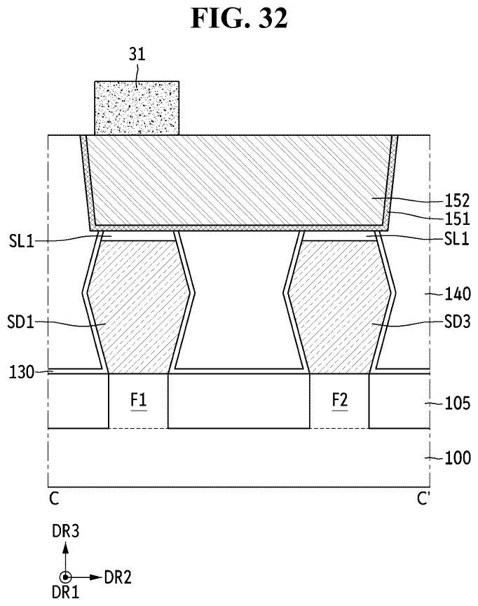

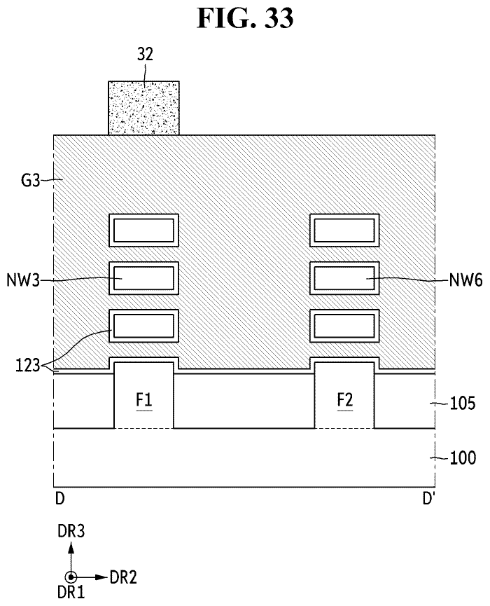

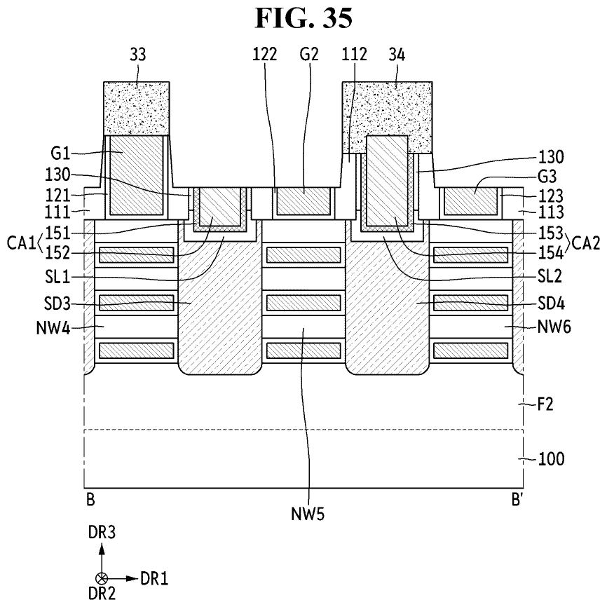

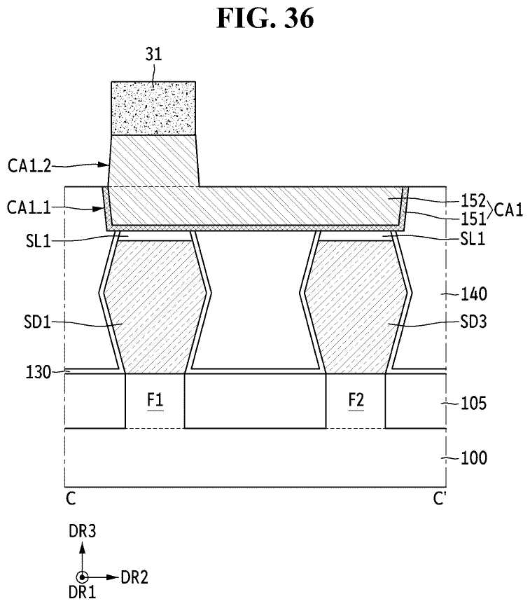

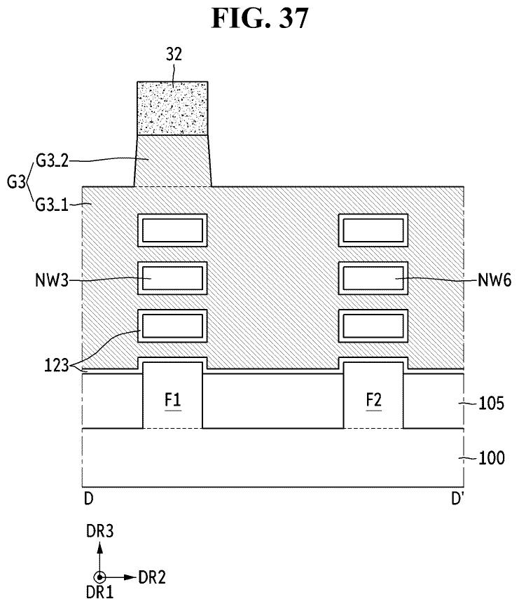

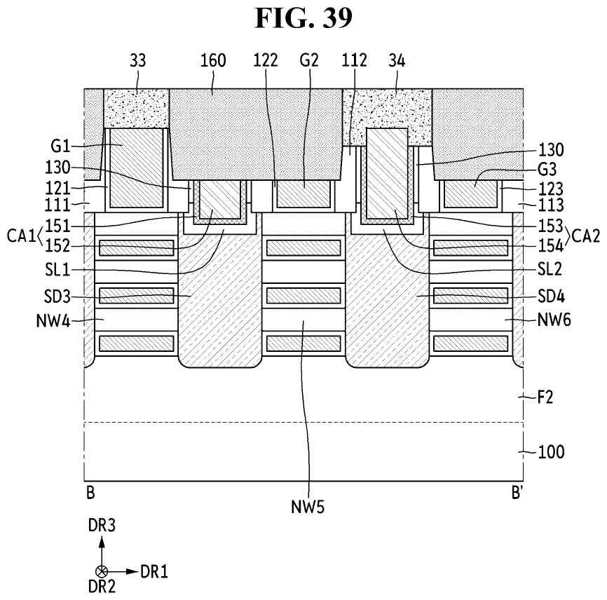

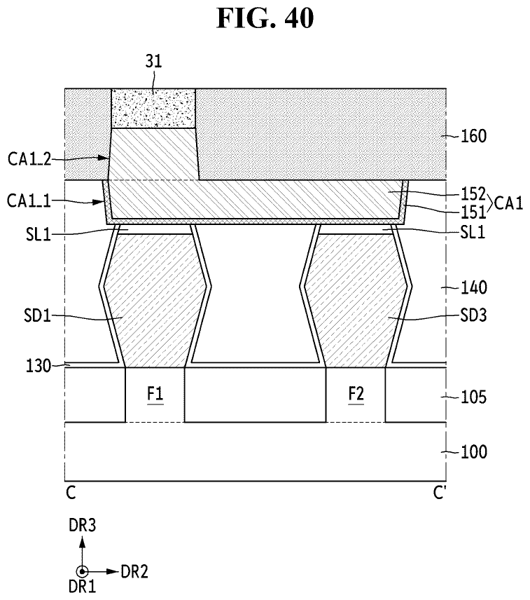

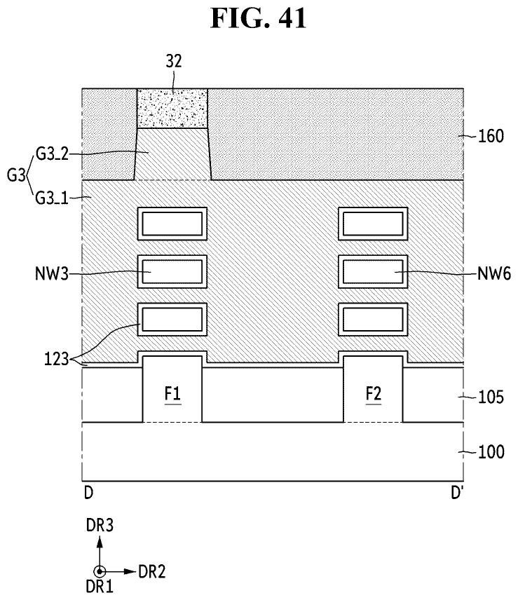

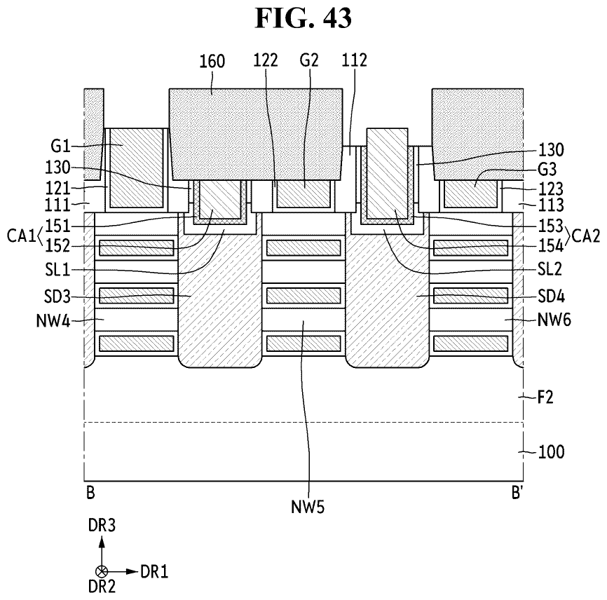

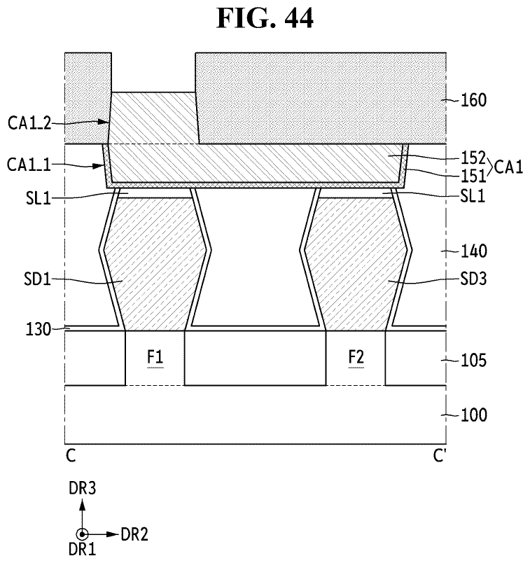

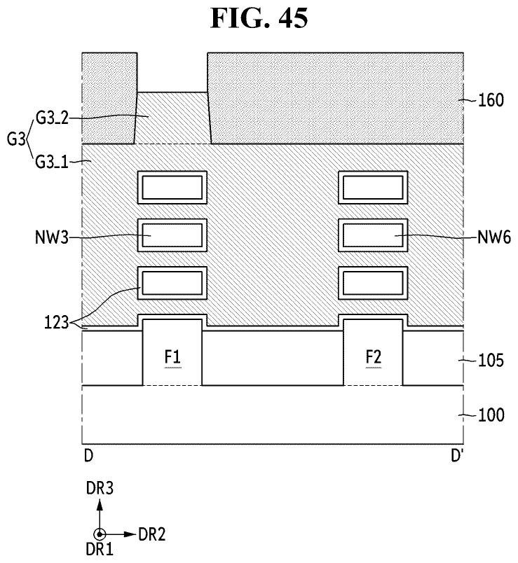

Hereinafter, the semiconductor device according to some embodiments of the present disclosure will be described with reference to FIGS. 2 to 49.

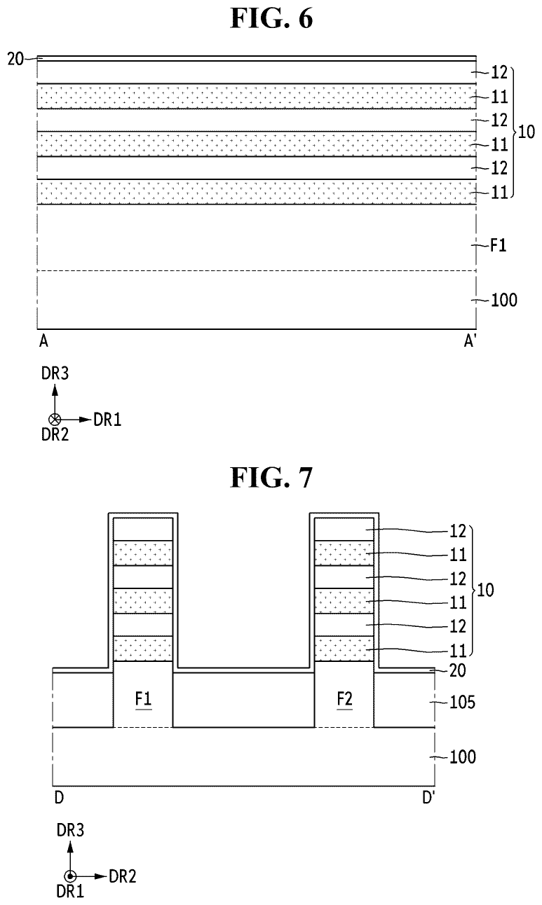

FIGS. 6 to 49 are intermediate stage diagrams for explaining the method of fabricating the semiconductor device according to some embodiments of the present disclosure.

Referring to FIGS. 6 and 7, a laminated structure 10 may be formed on the substrate 100. The laminated structure 10 may include a first semiconductor layer 11 and a second semiconductor layer 12 alternately stacked on the substrate 100. For example, the first semiconductor layer 11 may be formed at the lowermost portion of the laminated structure 10, and the second semiconductor layer 12 may be formed at the uppermost portion of the laminated structure 10. However, the present disclosure is not limited thereto. In some other embodiments, the first semiconductor layer 11 may also be formed at the uppermost portion of the laminated structure 10. The first semiconductor layer 11 may include, for example, silicon germanium (SiGe). The second semiconductor layer 12 may include, for example, silicon (Si).

Subsequently, a portion of the laminated structure 10 may be etched. While the laminated structure 10 is being etched, a portion of the substrate 100 may also be etched. Through this etching process, the first active pattern F1 and the second active pattern F2 may each be defined at the lower portion of the laminated structure 10 on the substrate 100. Each of the first and second active patterns F1, F2 may extend in the first horizontal direction DR1. The second active pattern F2 may be spaced apart from the first active pattern F1 in the second horizontal direction DR2. Subsequently, the field insulating layer 105 may be formed on the substrate 100. The field insulating layer 105 may surround the sidewall of each of the first and second active patterns F1, F2. For example, the upper surface of each of the first and second active patterns F1, F2 may be formed higher than the upper surface of the field insulating layer 105. Subsequently, a pad oxide layer 20 may be formed to cover the upper surface of the field insulating layer 105, the exposed sidewall of each of the first and second active patterns F1, F2, and the sidewalls and upper surface of the laminated structure 10. For example, the pad oxide layer 20 may be formed conformally. The pad oxide layer 20 may include, for example, silicon oxide (SiO₂).

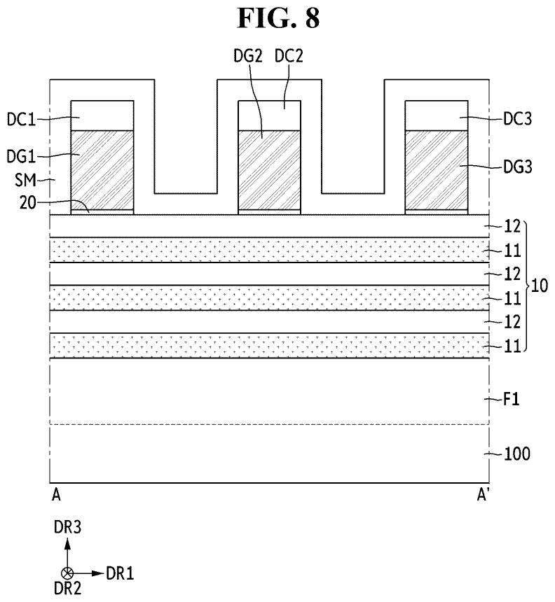

Referring to FIGS. 8 to 10, first to third dummy gates DG1, DG2, DG3 and first to third dummy capping patterns DC1, DC2, DC3 extending in the second horizontal direction DR2 may be formed on the pad oxide layer 20 on the laminated structure 10 and the field insulating layer 105. For example, the second dummy gate DG2 may be spaced apart from the first dummy gate DG1 in a first horizontal direction DR1. The third dummy gate DG3 may be spaced apart from the second dummy gate DG2 in the first horizontal direction DR1. The first dummy capping pattern DC1 may be disposed on the first dummy gate DG1. The second dummy capping pattern DC2 may be disposed on the second dummy gate DG2. The third dummy capping pattern DC3 may be disposed on the third dummy gate DG3.

While the first to third dummy gates DG1, DG2, DG3 and the first to third dummy capping patterns DC1, DC2, DC3 are being formed, the remaining pad oxide layer 20 on the substrate 100 may be removed, except for the portions overlapping each of the first to third dummy gates DG1, DG2, DG3 in the vertical direction DR3. Subsequently, the spacer material layer SM may be formed to cover the sidewall of each of the first to third dummy gates DG1, DG2, DG3, the sidewall and upper surface of each of the first to third dummy capping patterns DC1, DC2, DC3, the sidewalls and upper surfaces of the exposed laminated structure 10, and the upper surface of the field insulating layer 105. For example, the spacer material layer SM may be formed conformally. The spacer material layer SM may include, for example, at least one of silicon nitride (SiN), silicon oxycarbonitride (SiOCN), silicon boron carbonitride (SiBCN), silicon carbonitride (SiCN), silicon oxynitride (SiON), and combinations thereof.

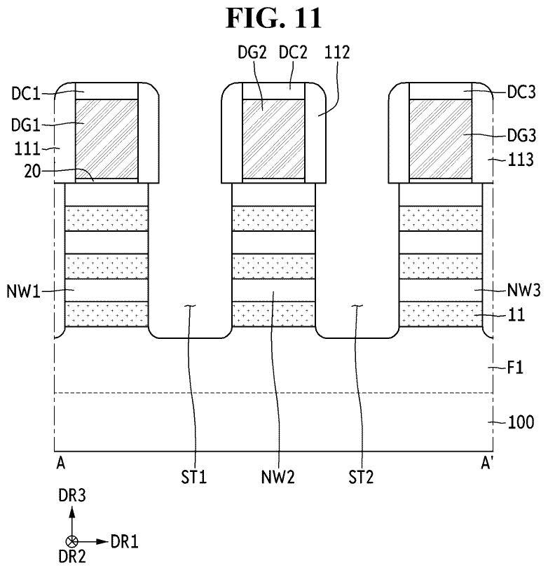

Referring to FIGS. 11 to 13, the laminated structure 10 (see FIG. 8) may be etched using the first to third dummy gates DG1, DG2, DG3 and the first to third dummy capping patterns DC1, DC2, DC3 as masks to form each of the first to fourth source/drain trenches ST1 to ST4. For example, the first source/drain trench ST1 may be formed between the first dummy gate DG1 and the second dummy gate DG2 on the first active pattern F1. The second source/drain trench ST2 may be formed between the second dummy gate DG2 and the third dummy gate DG3 on the first active pattern F1. The third source/drain trench ST3 may be formed between the first dummy gate DG1 and the second dummy gate DG2 on the second active pattern F2. The fourth source/drain trench ST4 may be formed between the second dummy gate DG2 and the third dummy gate DG3 on the second active pattern F2. For example, while each of the first to fourth source/drain trenches ST1 to ST4 is being formed, the spacer material layer SM (see FIG. 8) formed on the upper surface of each of the first to third dummy capping patterns DC1, DC2, DC3 and a portion of each of the first to third dummy capping patterns DC1, DC2, DC3 may be etched.

For example, the spacer material layer SM (see FIG. 8) remaining on the sidewall of each of the first to third dummy capping patterns DC1, DC2, DC3 and the first to third dummy gates DG1, DG2, DG3 may be defined as the first to third gate spacers 111, 112, 113. For example, after each of the first and second source/drain trenches ST1, ST2 is formed, each of the second semiconductor layers 12 (see FIG. 8) remaining on the lower part of each of the first to third dummy gates DG1, DG2, DG3 on the first active pattern F1 may be defined as each of the first to third plurality of nanosheets NW1, NW2, NW3. Further, after each of the third and fourth source/drain trenches ST3, ST4 is formed, each of the second semiconductor layers 12 (see FIG. 8) remaining on the lower part of each of the first to third dummy gates DG1, DG2, DG3 on the second active pattern F2 may be defined as each of the fourth to sixth plurality of nanosheets NW4, NW5, NW6.

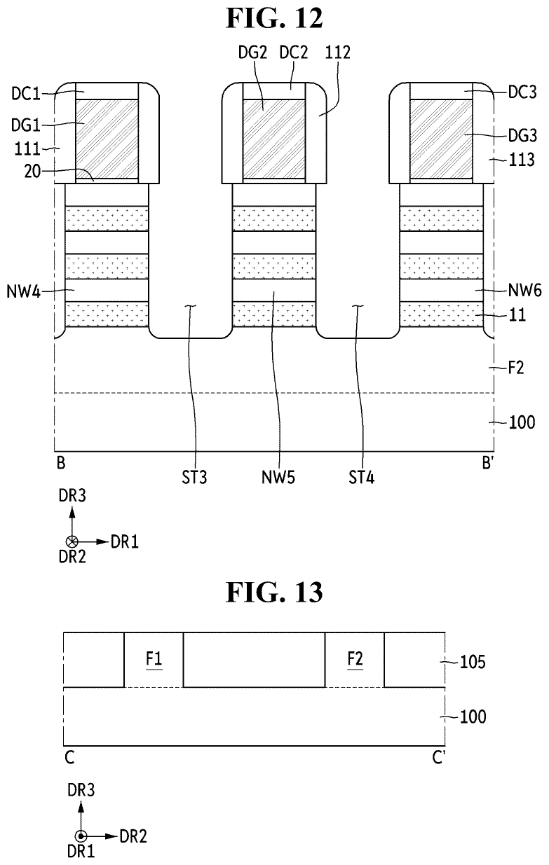

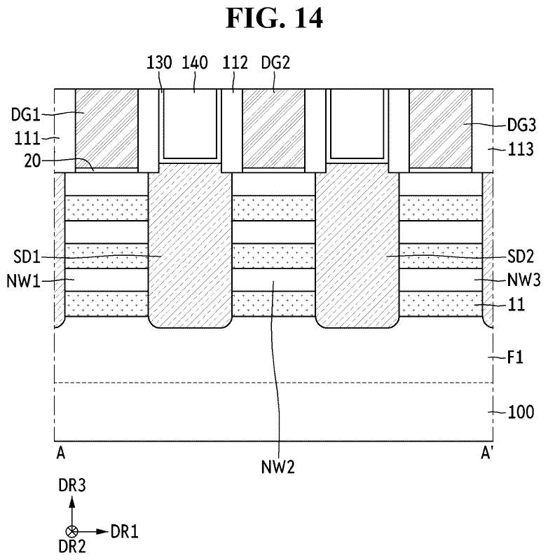

Referring now to FIGS. 14 to 16, the first source/drain region SD1 is formed inside the first source/drain trench ST1 (see FIG. 11), and the second source/drain region SD2 is formed inside the second source/drain trench ST2 (see FIG. 11), the third source/drain region SD3 may be formed inside the third source/drain trench ST3 (see FIG. 12), and the fourth source/drain region SD4 may be formed inside the fourth source/drain trench ST4 (see FIG. 12).

Subsequently, the first etch stop layer 130 and the first interlayer insulating layer 140 may be formed sequentially on the upper surface of the field insulating layer 105, the surface of each of the first to fourth source/drain regions SD1 to SD4, the exposed surface of each of the first to third gate spacers 111, 112, 113, and the upper surface of each of the first to third dummy capping patterns DC1, DC2, DC3 (see FIGS. 11 and 12). For example, the first etch stop layer 130 may be formed conformally. Subsequently, the upper surface of each of the first to third dummy gates DG1, DG2, DG3 may be exposed by performing a planarization process.

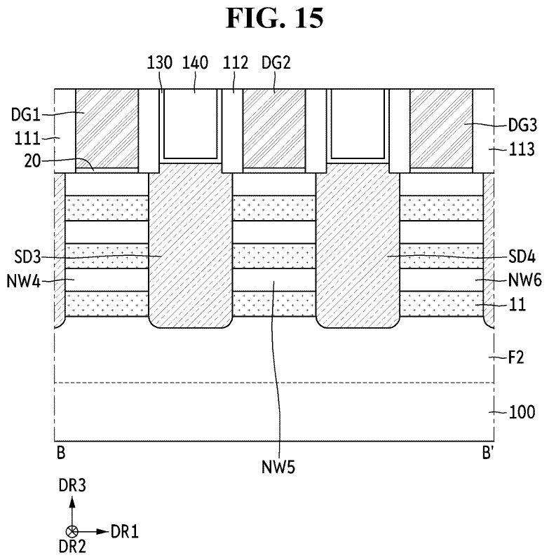

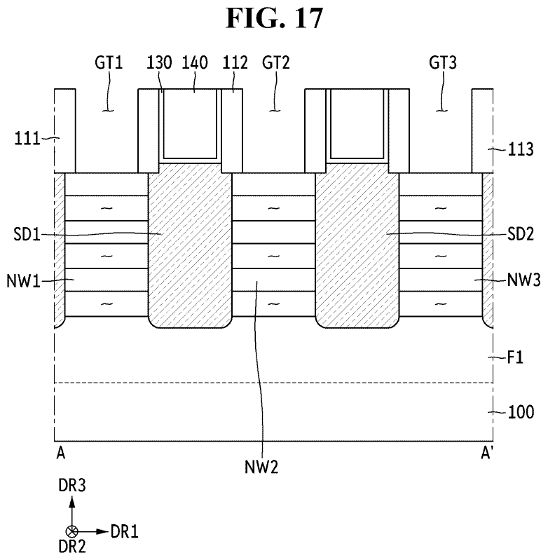

Referring to FIGS. 17 to 19, each of the first to third dummy gates DG1, DG2, DG3 (see FIGS. 14 and 15), the pad oxide layer 20 (see FIGS. 14 and 15), and the first semiconductor layer 11 (see FIGS. 14 and 15) may be etched. The portions in which the first dummy gate DG1 (see FIGS. 14 and 15), the pad oxide layer 20 (see FIGS. 14 and 15), and the first semiconductor layer 11 (see FIGS. 14 and 15) are each etched may be defined as the first gate trench GT1. The portions in which the second dummy gate DG2 (see FIGS. 14 and 15), the pad oxide layer 20 (see FIGS. 14 and 15), and the first semiconductor layer 11 (see FIGS. 14 and 15) are each etched may be defined as the second gate trench GT2. The portions in which the third dummy gate DG3 (see FIGS. 14 and 15), the pad oxide layer 20 (see FIGS. 14 and 15), and the first semiconductor layer 11 (see FIGS. 14 and 15) are each etched may be defined as the third gate trench GT3.

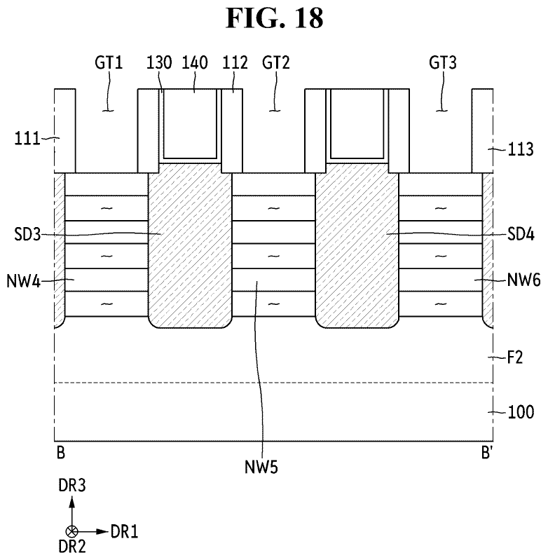

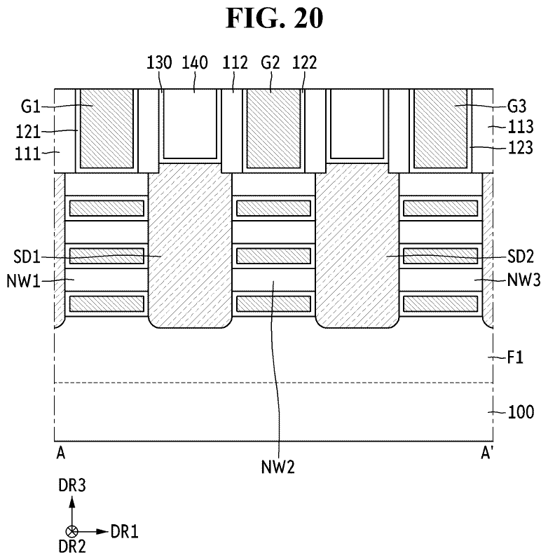

Referring to FIGS. 20 to 22, the first gate insulating layer 121 and the first gate electrode G1 may be sequentially formed inside the first gate trench GT1 (see FIGS. 17 and 18). The first gate electrode G1 may surround each of the first and fourth plurality of nanosheets NW1, NW4. The second gate insulating layer 122 and the second gate electrode G2 may be formed sequentially inside the second gate trench GT2 (see FIGS. 17 and 18). The second gate electrode G2 may surround each of the second and fifth plurality of nanosheets NW2, NW5. The third gate insulating layer 123 and the third gate electrode G3 may be formed sequentially inside the third gate trench GT3 (see FIGS. 17 and 18). The third gate electrode G3 may surround each of the third and sixth plurality of nanosheets NW3, NW6.

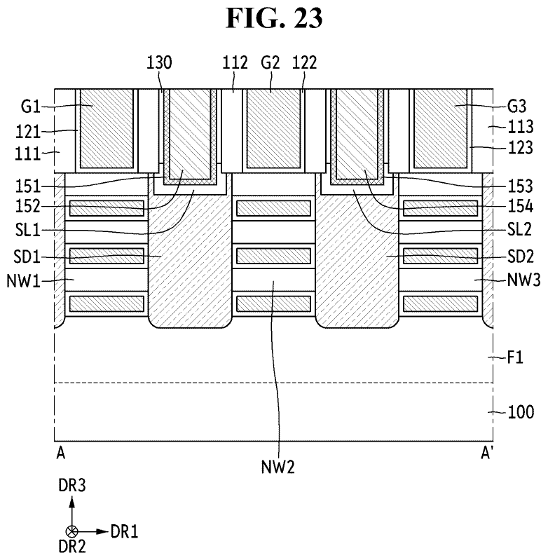

Referring to FIGS. 23 to 25, the first contact barrier layer 151 and the first contact filling layer 152 may be formed inside the first interlayer insulating layer 140. For example, the first contact barrier layer 151 and the first contact filling layer 152 may be formed between the first gate electrode G1 and the second gate electrode G2. For example, the first contact barrier layer 151 may be in contact with each of the first etch stop layer 130 and the first interlayer insulating layer 140. For example, the first contact barrier layer 151 may be formed conformally. For example, the first contact filling layer 152 may fill the space between the first contact barrier layer 151. That is, the first contact barrier layer 151 may be formed along the sidewalls and the lower surface of the first contact filling layer 152.

Further, the second contact barrier layer 153 and the second contact filling layer 154 may be formed inside the first interlayer insulating layer 140. For example, the second contact barrier layer 153 and the second contact filling layer 154 may be formed between the second gate electrode G2 and the third gate electrode G3. For example, the second contact barrier layer 153 may be in contact with each of the first etch stop layer 130 and the first interlayer insulating layer 140. For example, the second contact barrier layer 153 may be formed conformally. For example, the second contact filling layer 154 may fill the space between the second contact barrier layer 153. That is, the second contact barrier layer 153 may be formed along the sidewalls and the lower surface of the second contact filling layer 154.

For example, the upper surface of each of the first to third gate electrodes G1, G2, G3, the first to third gate spacers 111, 112, 113, the first to third gate insulating layers 121, 122, 123, the first and second contact barrier layers 151, 153, the first and second contact filling layers 152, 154, and the first interlayer insulating layer 140 may be formed on the same plane. While each of the first and second contact barrier layers 151, 153 is being formed, each of the first and second silicide layers SL1, SL2 may be formed. For example, the first silicide layer SL1 may be formed along the interface between each of the first and third source/drain regions SD1, SD3 and the first contact barrier layer 151. Further, the second silicide layer SL2 may be formed along the interface between each of the second and fourth source/drain regions SD2, SD4 and the second contact barrier layer 153.

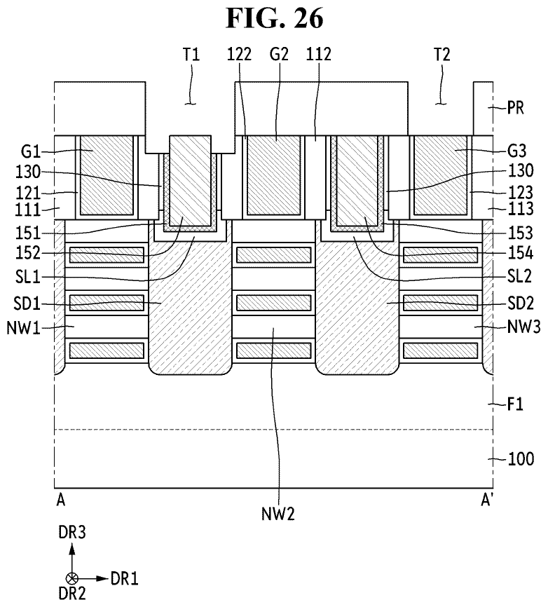

Referring to FIGS. 26 to 29, a photoresist pattern PR may be formed on the upper surface of each of the first to third gate electrodes G1, G2, G3, the first to third gate spacers 111, 112, 113, the first to third gate insulating layers 121, 122, 123, the first and second contact barrier layers 151, 153, the first and second contact filling layers 152, 154, and the first interlayer insulating layer 140. For example, first to fourth trenches T1 to T4 may be formed inside the photoresist pattern PR.

For example, the first trench T1 may penetrate the photoresist pattern PR in the vertical direction DR3 on the first active pattern F1 to expose a portion of the sidewall and the upper surface of the first contact filling layer 152 in the first horizontal direction DR1. For example, while the first trench T1 is being formed, a portion of the first contact barrier layer 151 formed on the sidewall of the first contact filling layer 152 in the first horizontal direction DR1, a portion of the first etch stop layer 130, a portion of the first gate spacer 111, and a portion of the second gate spacer 112 may be etched. For example, the second trench T2 may penetrate the photoresist pattern PR in the vertical direction DR3 on the first active pattern F1 to expose the upper surface of the third gate electrode G3 and the upper surface of the third gate insulating layer 123.

For example, the third trench T3 may penetrate the photoresist pattern PR in the vertical direction DR3 on the second active pattern F2 to expose the upper surface of the first gate electrode G1 and the upper surface of the first gate insulating layer 121. For example, the fourth trench T4 may penetrate the photoresist pattern PR in the vertical direction DR3 on the second active pattern F2 to expose a portion of the sidewall and the upper surface of the second contact filling layer 154 in the first horizontal direction DR1. For example, while the fourth trench T4 is being formed, a portion of the second contact barrier layer 153 formed on the sidewall of the second contact filling layer 154 in the first horizontal direction DR1, a portion of the first etch stop layer 130, a portion of the second gate spacer 112, and a portion of the third gate spacer 113 may be etched.

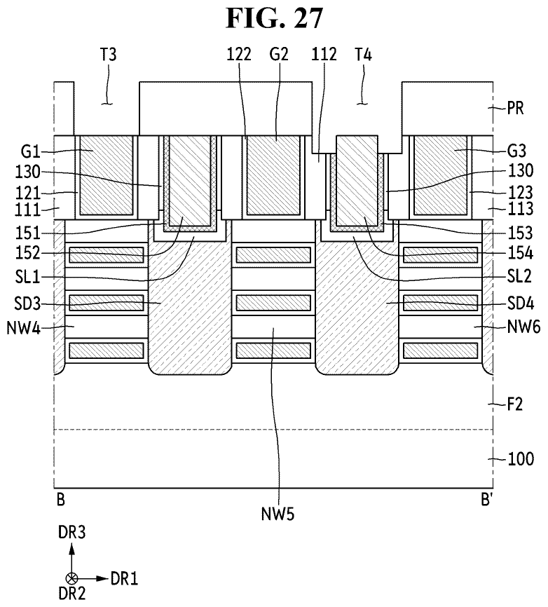

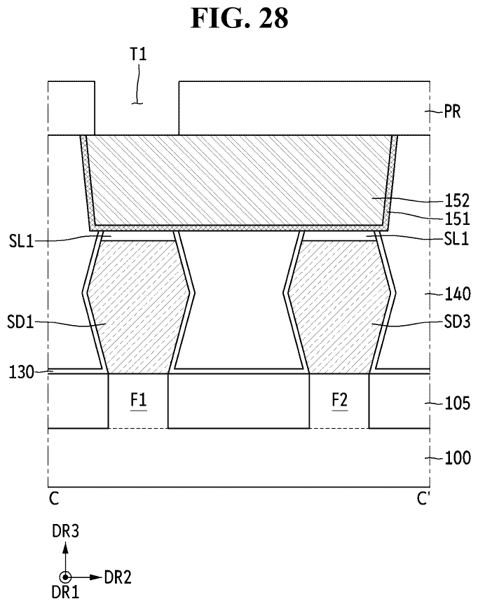

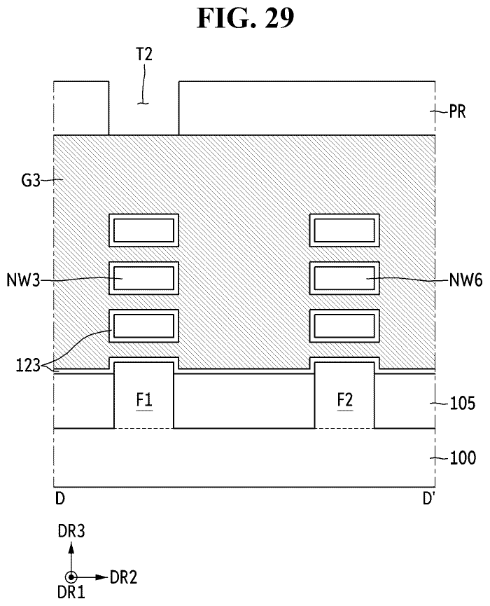

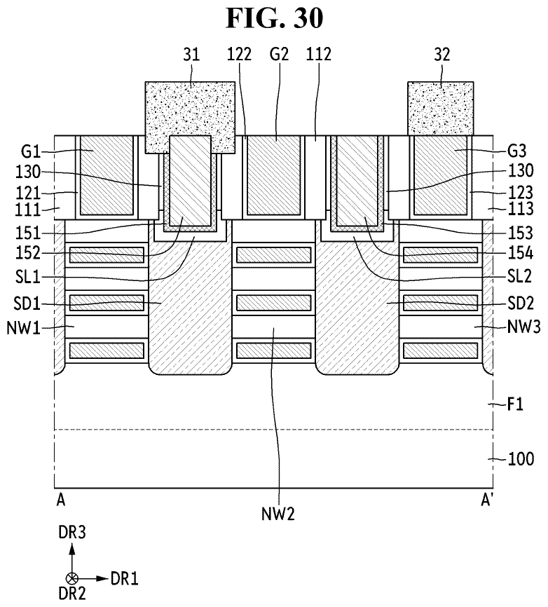

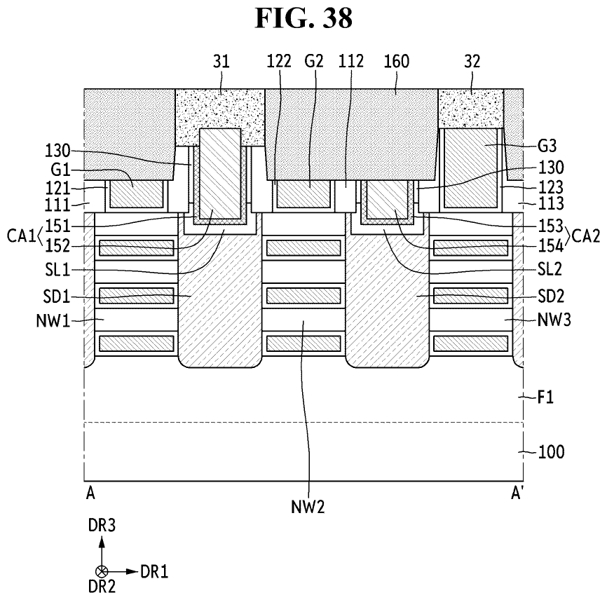

Referring to FIGS. 30 to 33, a first sacrificial pattern 31 may be formed inside the first trench T1 (see FIGS. 26 and 28), a second sacrificial pattern 32 may be formed inside the second trench T2 (see FIGS. 26 and 29), a third sacrificial pattern 33 may be formed inside the third trench T3 (see FIG. 27), and a fourth sacrificial pattern 34 may be formed inside the fourth trench T4 (see FIG. 27). Each of the first to fourth sacrificial patterns 31 to 34 may include an insulating material. For example, each of the first to fourth sacrificial patterns 31 to 34 may include a material having an etch selectivity with the second interlayer insulating layer 160 (see FIGS. 38 to 41), which will be described later. For example, each of the first to fourth sacrificial patterns 31 to 34 may include silicon oxide (SiO₂), but the present disclosure is not limited thereto. Subsequently, the photoresist pattern PR may be removed.

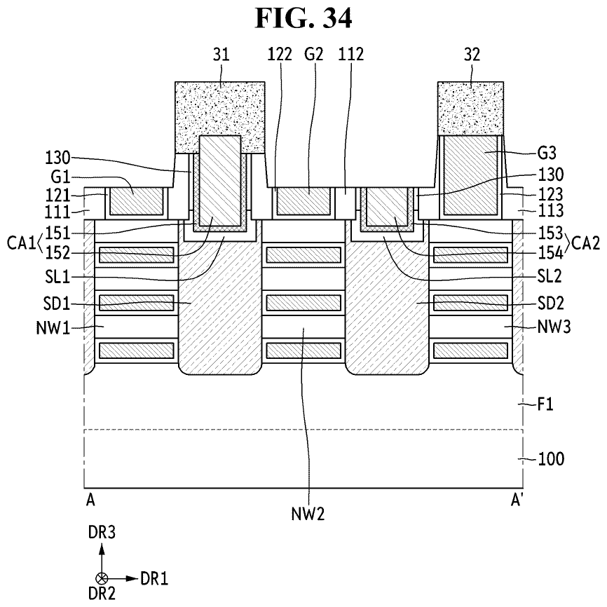

Referring to FIGS. 34 to 37, using each of the first to fourth sacrificial patterns 31 to 34 as a mask, the remaining portions except for the portions in which each of the first to fourth sacrificial patterns 31 to 34 is formed may be etched. After such an etching process is completed, the remaining first contact barrier layer 151 and the first contact filling layer 152 may be defined as the first source/drain contact CA1, and the remaining second contact barrier layer 153 and the second contact filling layer 154 may be defined as the second source/drain contact CA2.

Referring to FIGS. 38 to 41, the second interlayer insulating layer 160 may be formed on the remaining portions except for the portions overlapping with each of the first to fourth sacrificial patterns 31 to 34 in the vertical direction DR3.

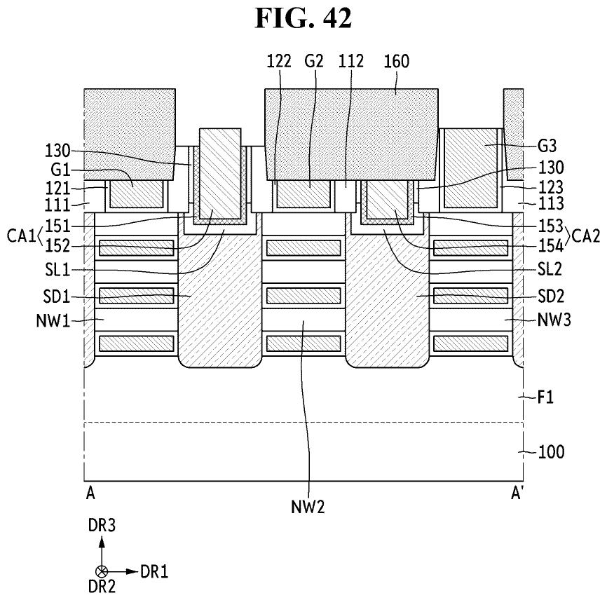

Referring to FIGS. 42 to 45, each of the first to fourth sacrificial patterns 31 to 34 (see FIGS. 38 to 41) may be etched.

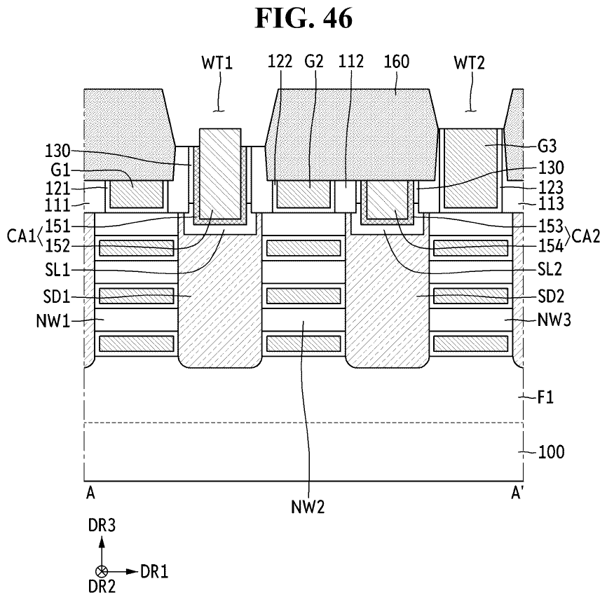

Referring now to FIGS. 46 to 49, a portion of the sidewall of the second interlayer insulating layer 160 exposed to the etched portion of each of the first to fourth sacrificial patterns 31 to 34 (see FIGS. 38 to 41) may be etched. Through this etching process, each of the first to fourth wiring trenches WT1 to WT4 may be formed inside the second interlayer insulating layer 160. For example, the first wiring trench WT1 may be formed on the first source/drain contact CA1 on the first active pattern F1. The second wiring trench WT2 may be formed on the third gate electrode G3 on the first active pattern F1. The third wiring trench WT3 may be formed on the first gate electrode G1 on the second active pattern F2. The fourth wiring trench WT4 may be formed on the second source/drain contact CA2 on the second active pattern F2.

For example, the width of each of the first to fourth wiring trenches WT1 to WT4 in the first horizontal direction DR1 may increase sequentially as they get closer to the upper surface of the second interlayer insulating layer 160. Furthermore, the width of each of the first to fourth wiring trenches WT1 to WT4 in the second horizontal direction DR2 may increase sequentially as they get closer to the upper surface of the second interlayer insulating layer 160.

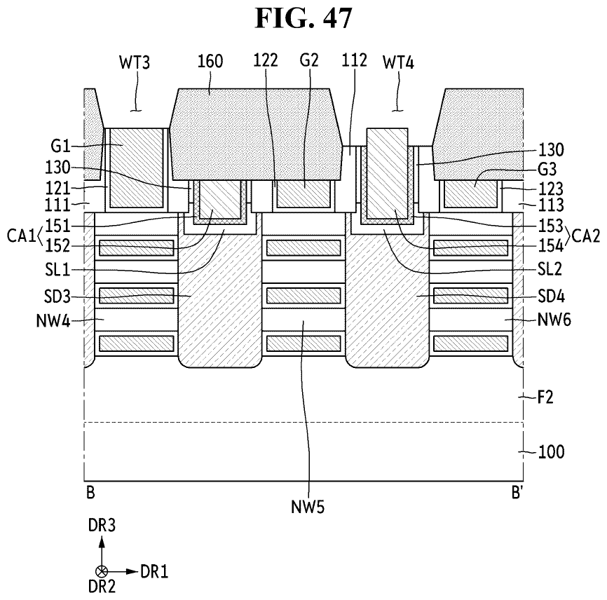

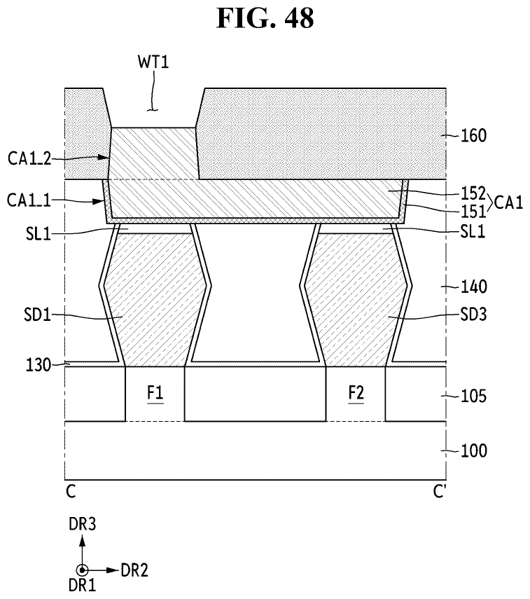

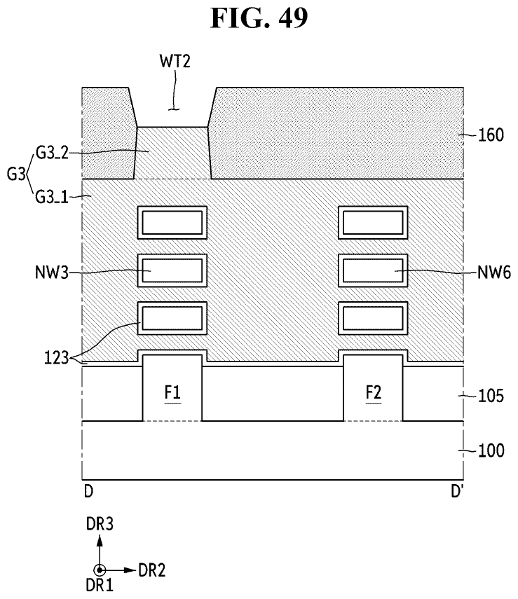

Referring to FIGS. 2 to 5, the first wiring pattern 181 may be formed inside the first wiring trench WT1 (see FIGS. 46 and 48) and on the upper surface of the second interlayer insulating layer 160 adjacent to the first wiring trench WT1 (see FIGS. 46 and 48). The second wiring pattern 182 may be formed inside the second wiring trench WT2 (see FIGS. 46 and 49) and on the upper surface of the second interlayer insulating layer 160 adjacent to the second wiring trench WT2 (see FIGS. 46 and 49). The third wiring pattern 183 may be formed inside the third wiring trench WT3 (see FIG. 47) and on the upper surface of the second interlayer insulating layer 160 adjacent to the third wiring trench WT3 (see FIG. 47). The fourth wiring pattern 184 may be formed inside the fourth wiring trench WT4 (see FIG. 47) and on the upper surface of the second interlayer insulating layer 160 adjacent to the fourth wiring trench WT4 (see FIG. 47). Subsequently, the third interlayer insulating layer 170 may be formed on the upper surface of the second interlayer insulating layer 160, surrounding the sidewall of each of the first to fourth wiring patterns 181 to 184. Through such a fabrication process, the semiconductor device shown in FIGS. 2 to 5 may be fabricated.

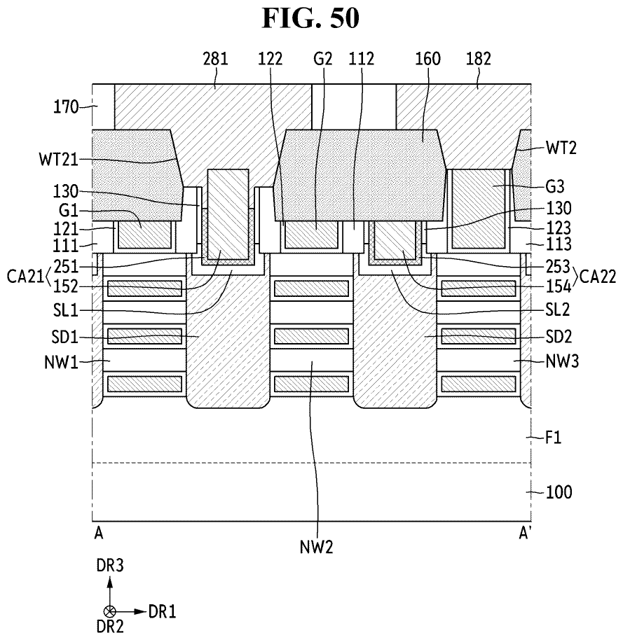

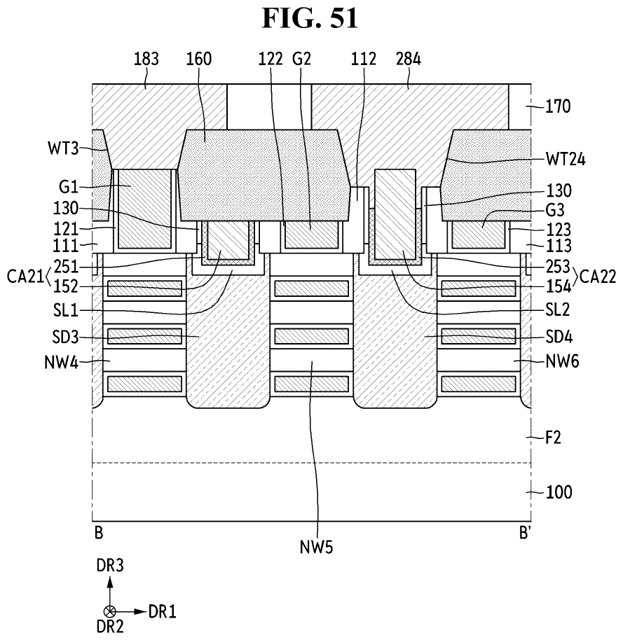

Hereinafter, the semiconductor device according to some other embodiments of the present disclosure will be described with reference to FIGS. 50 and 51. The description will focus on the differences from the semiconductor device shown in FIGS. 1 to 5.

FIGS. 50 and 51 are cross-sectional views for explaining semiconductor device according to some other embodiments of the present disclosure.

Referring to FIGS. 50 and 51, in the semiconductor device according to some other embodiments of the present disclosure, at least a portion of the first wiring pattern 281 may be disposed between both sidewalls of the first source/drain contact CA21 in the first horizontal direction DR1 and the first etch stop layer 130, and at least a portion of the fourth wiring pattern 284 may be disposed between both sidewalls of the second source/drain contact CA22 in the first horizontal direction DR1 and the first etch stop layer 130.

For example, on the first active pattern F1, the upper surface of the first contact barrier layer 251 may be formed lower than each of the upper surface of the adjacent first etch stop layer 130, the upper surface of the adjacent first gate spacer 111, and the upper surface of the adjacent second gate spacer 112. On the first active pattern F1, the first wiring trench WT21 may include the region on the upper surface of the first contact barrier layer 251 between both sidewalls of the first contact filling layer 152 in the first horizontal direction DR1 and the first etch stop layer 130. That is, on the first active pattern F1, the first wiring pattern 281 may be disposed on the upper surface of the first contact barrier layer 251 between both sidewalls of the first contact filling layer 152 in the first horizontal direction DR1 and the first etch stop layer 130.

For example, on the second active pattern F2, the upper surface of the second contact barrier layer 253 may be formed lower than each of the upper surface of the adjacent first etch stop layer 130, the upper surface of the adjacent second gate spacer 112, and the upper surface of the adjacent third gate spacer 113. On the second active pattern F2, the fourth wiring trench WT24 may include the region on the upper surface of the second contact barrier layer 253 between both sidewalls of the second contact filling layer 154 in the first horizontal direction DR1 and the first etch stop layer 130. That is, on the second active pattern F2, the fourth wiring pattern 284 may be disposed on the upper surface of the second contact barrier layer 253 between both sidewalls of the second contact filling layer 154 in the first horizontal direction DR1 and the first etch stop layer 130.

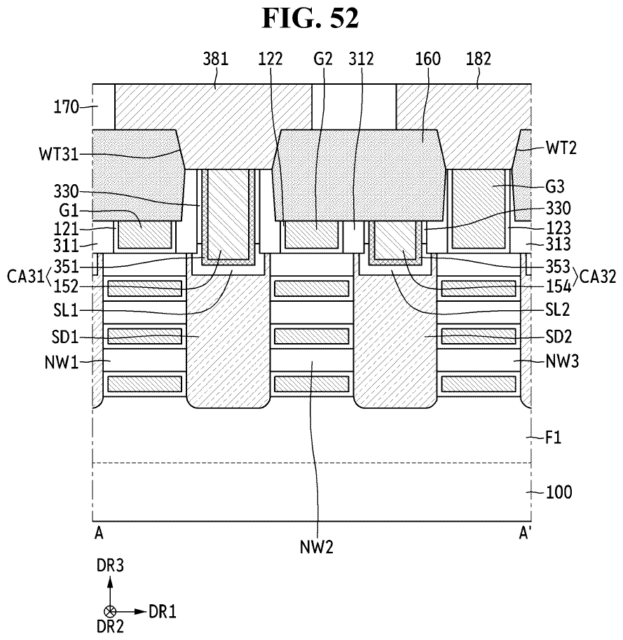

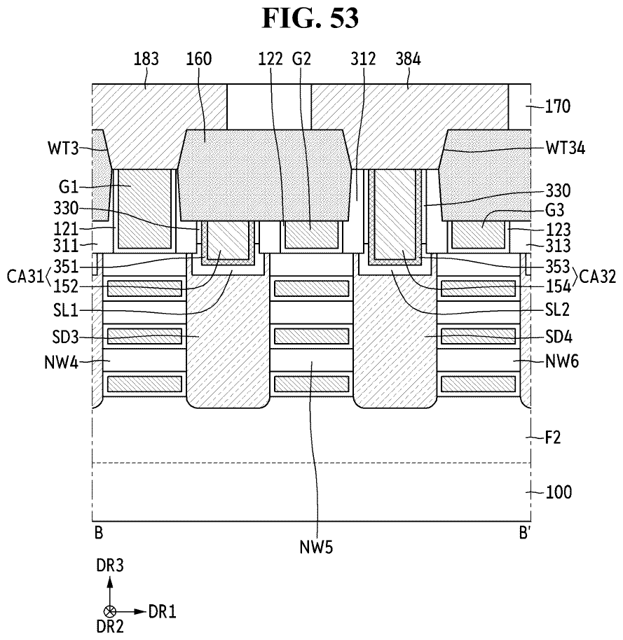

Hereinafter, with reference to FIGS. 52 and 53, the semiconductor device according to yet some other embodiments of the present disclosure will be described. The description will focus on the differences from the semiconductor device shown in FIGS. 1 to 5.

FIGS. 52 and 53 are cross-sectional views for explaining the semiconductor device according to another several embodiments of the present disclosure.

Referring to FIGS. 52 and 53, in the semiconductor device according to still some other embodiments of the present disclosure, each of the uppermost surface of the first contact barrier layer 351 and the uppermost surface of the first contact filling layer 152 that is in contact with the lower surface of the first wiring pattern 381 may be formed on the same plane, and each of the uppermost surface of the second contact barrier layer 353 and the uppermost surface of the second contact filling layer 154 that is in contact with the lower surface of the fourth wiring pattern 384 may be formed on the same plane.

For example, on the first active pattern F1, the uppermost surface of the first contact barrier layer 351 may be formed on the same plane as each of the uppermost surface of the first contact filling layer 152, the upper surface of the adjacent first etch stop layer 330, the upper surface of the adjacent first gate spacer 311, and the upper surface of the adjacent second gate spacer 312. On the first active pattern F1, the lower surface of the first wiring trench WT31 may have a planar shape. That is, on the first active pattern F1, the upper surface of the first source/drain contact CA31 that is in contact with the lower surface of the first wiring pattern 381 may have a planar shape. For example, on the first active pattern F1, the first wiring pattern 381 is not in contact with the sidewalls of the first contact filling layer 152 in the first horizontal direction DR1.

For example, on the second active pattern F2, the uppermost surface of the second contact barrier layer 353 may be formed on the same plane as each of the uppermost surface of the second contact filling layer 154, the upper surface of the adjacent first etch stop layer 330, the upper surface of the adjacent second gate spacer 312, and the upper surface of the adjacent third gate spacer 313. On the second active pattern F2, the lower surface of the fourth wiring trench WT34 may have a planar shape. That is, on the second active pattern F2, the upper surface of the second source/drain contact CA32 that is in contact with the lower surface of the fourth wiring pattern 384 may have a planar shape. For example, on the second active pattern F2, the fourth wiring pattern 384 is not in contact with the sidewalls of the second contact filling layer 154 in the first horizontal direction DR1.

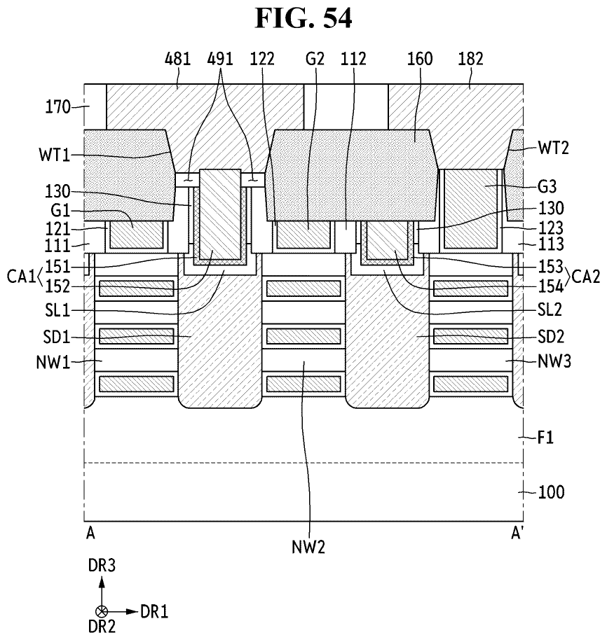

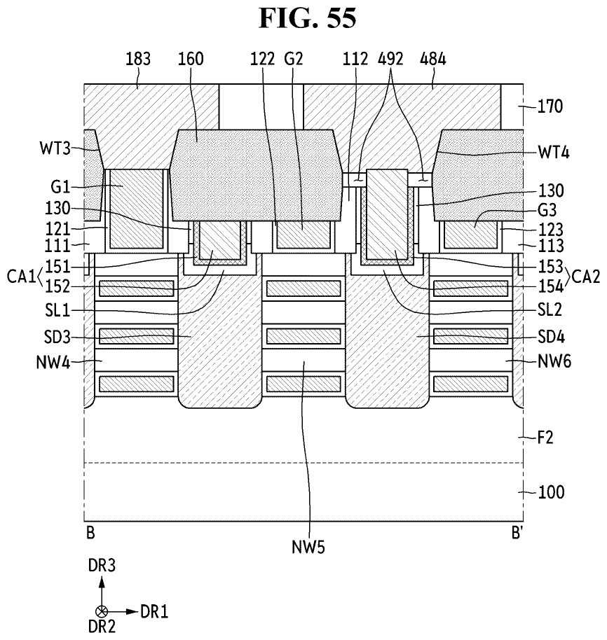

Hereinafter, with reference to FIGS. 54 and 55, the semiconductor device according to some other embodiments of the present disclosure will be described. The description will focus on the differences from the semiconductor device shown in FIGS. 1 to 5.

FIGS. 54 and 55 are cross-sectional views for explaining the semiconductor device according to another several embodiments of the present disclosure.

Referring to FIGS. 54 and 55, in the semiconductor device according to some other embodiments of the present disclosure, a first air gap 491 may be formed between both sidewalls of the first contact filling layer 152 in a first horizontal direction DR1 and the second interlayer insulating layer 160 on the first active pattern F1, and a second air gap 492 may be formed between both sidewalls of the second contact filling layer 154 in the first horizontal direction DR1 and the second interlayer insulating layer 160 on the second active pattern F2.

For example, a first air gap 491 may be formed on both sidewalls of the first contact filling layer 152 in the first horizontal direction DR1 on the lower portion of the first wiring pattern 481. For example, the first air gap 491 may expose a portion of the lower surface of the first wiring pattern 481, a portion of the sidewalls of the first contact filling layer 152 in the first horizontal direction DR1, a portion of the sidewalls of the second interlayer insulating layer 160, the upper surface of the first contact barrier layer 151, the upper surface of the first etch stop layer 130, the upper surface of the first gate spacer 111, and the upper surface of the second gate spacer 112.

For example, a second air gap 492 may be formed on both sidewalls of the second contact filling layer 154 in the first horizontal direction DR1 on the lower portion of the fourth wiring pattern 484. For example, the second air gap 492 may expose a portion of the lower surface of the fourth wiring pattern 484, a portion of the sidewalls of the second contact filling layer 154 in the first horizontal direction DR1, a portion of the sidewalls of the second interlayer insulating layer 160, the upper surface of the second contact barrier layer 153, the upper surface of the first etch stop layer 130, the upper surface of the second gate spacer 112, and the upper surface of the third gate spacer 113.

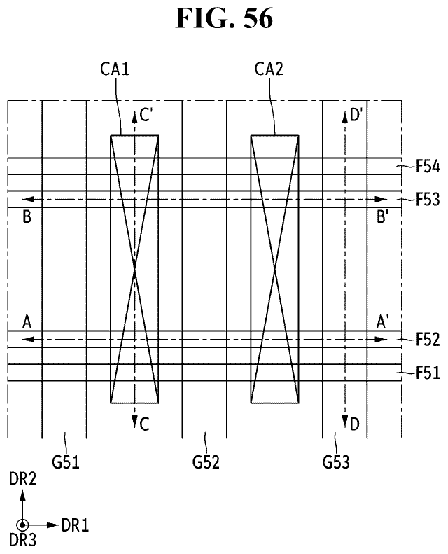

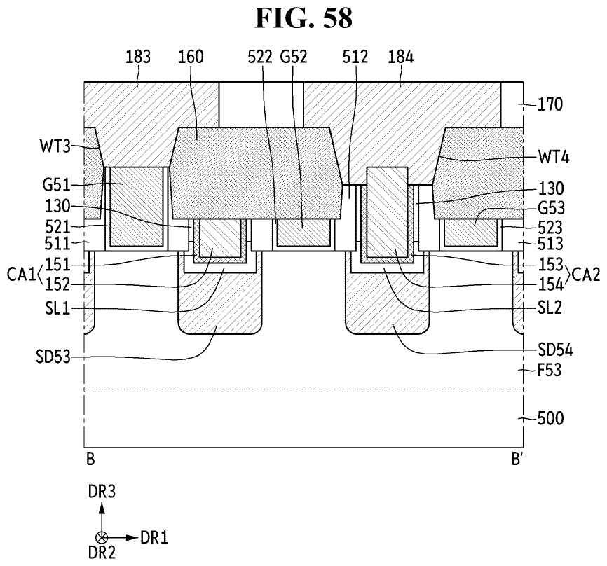

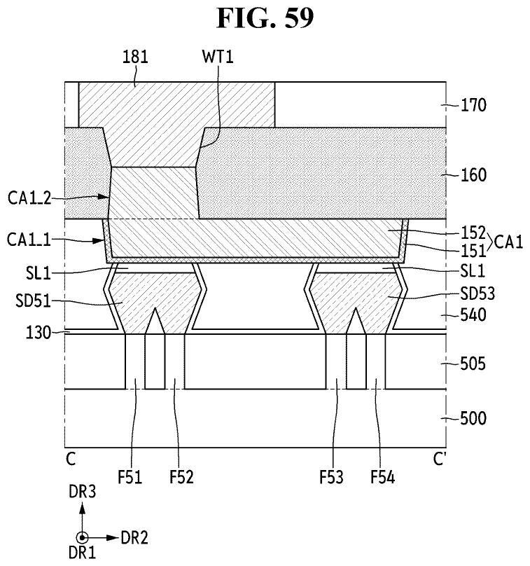

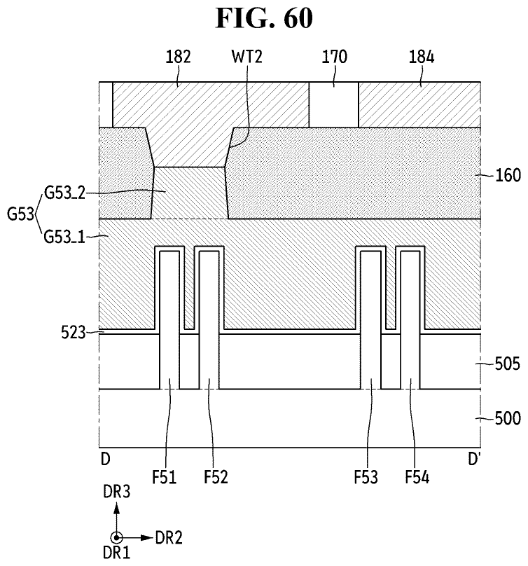

Hereinafter, with reference to FIGS. 56 to 60, the semiconductor device according to some other embodiments of the present disclosure will be described. The description will focus on the differences from the semiconductor device shown in FIGS. 1 to 5.

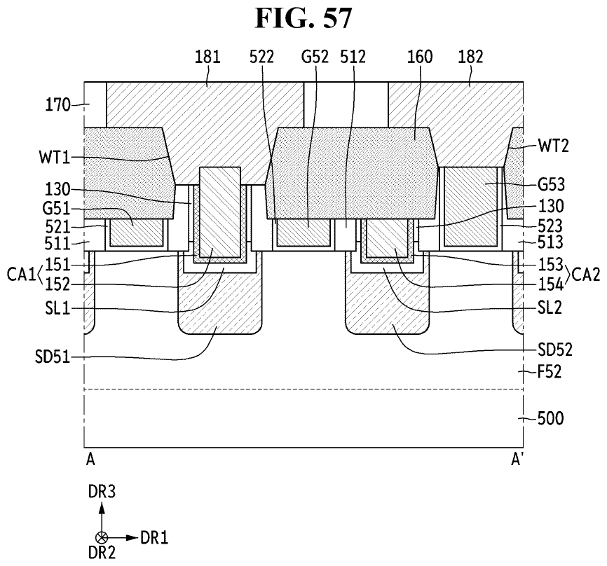

FIG. 56 is a layout diagram for explaining the semiconductor device according to another several embodiments of the present disclosure. FIGS. 57 to 60 are cross-sectional views for explaining the semiconductor device according to yet some other embodiments of the present disclosure.

Referring to FIGS. 56 to 60, the semiconductor device according to still some other embodiments of the present disclosure may include a FinFET (Fin Field-Effect Transistor). For example, the semiconductor device according to other several embodiments of the present disclosure may include the substrate 500, first to fourth active patterns F51, F52, F53, F54, the field insulating layer 505, first to third gate electrodes G51, G52, G53, first to third gate spacers 511, 512, 513, and first to third gate insulating layers 521, 522, 523, first to fourth source/drain regions SD51, SD52, SD53, SD54, the first etch stop layer 130, the first interlayer insulating layer 540, first and second source/drain contacts CA1, CA2, first and second silicide layers SL1, SL2, the second interlayer insulating layer 160, the third interlayer insulating layer 170, and first to fourth wiring patterns 181, 184. Hereinafter, the configurations depicted in FIGS. 1 to 5 will not be described.

Each of the first to fourth active patterns F51, F52, F53, F54 may extend in the first horizontal direction DR1 on the substrate 500. The second active pattern F52 may be spaced apart from the first active pattern F51 in the second horizontal direction DR2. The third active pattern F53 may be spaced apart from the second active pattern F52 in the second horizontal direction DR2. The fourth active pattern F54 may be spaced apart from the third active pattern F53 in the second horizontal direction DR2. For example, the spacing in the second horizontal direction DR2 between the first and second active patterns F51, F52 may be the same as the spacing in the second horizontal direction DR2 between the third and fourth active patterns F53, F54. For example, the spacing in the second horizontal direction DR2 between the second and third active patterns F52, F53 may be greater than each of the spacing in the second horizontal direction DR2 between the first and second active patterns F51, F52 and the spacing in the second horizontal direction DR2 between the third and fourth active patterns F53, F54. The field insulating layer 505 may surround a portion of the sidewall of each of the first to fourth active patterns F51, F52, F53, F54 on the upper surface of the substrate 500.

Each of the first to third gate electrodes G51, G52, G53 may extend in the second horizontal direction DR2 on the field insulating layer 505 and each of the first to fourth active patterns F51, F52, F53, F54. The second gate electrode G52 may be spaced apart from the first gate electrode G51 in the first horizontal direction DR1. The third gate electrode G53 may be spaced apart from the second gate electrode G52 in the first horizontal direction DR1. For example, the first portion G53_1 of the third gate electrode G53 may extend in the second horizontal direction DR2 on the field insulating layer 505 and each of the first to fourth active patterns F51, F52, F53, F54. The second portion G53_2 of the third gate electrode G53 may protrude from the first portion G53_1 of the third gate electrode G53 in the vertical direction DR3. For example, the second portion G53_2 of the third gate electrode G53 may overlap with each of the first and second active patterns F51, F52 in the vertical direction DR3.

The first gate spacer 511 may extend in the second horizontal direction DR2 on the field insulating layer 505 and each of the first to fourth active patterns F51, F52, F53, F54 along both sidewalls of the first gate electrode G51. The second gate spacer 512 may extend in the second horizontal direction DR2 on the field insulating layer 505 and each of the first to fourth active patterns F51, F52, F53, F54 along both sidewalls of the second gate electrode G52. The third gate spacer 513 may extend in the second horizontal direction DR2 on the field insulating layer 505 and each of the first to fourth active patterns F51, F52, F53, F54 along both sidewalls of the third gate electrode G53.

The first gate insulating layer 521 may be disposed between the first gate electrode G51 and each of the first to fourth active patterns F51, F52, F53, F54. The first gate insulating layer 521 may be disposed between the first gate electrode G51 and the field insulating layer 505. The first gate insulating layer 521 may be disposed between the first gate electrode G51 and the first gate spacer 511. The second gate insulating layer 522 may be disposed between the second gate electrode G52 and each of the first to fourth active patterns F51, F52, F53, F54. The second gate insulating layer 522 may be disposed between the second gate electrode G52 and the field insulating layer 505. The second gate insulating layer 522 may be disposed between the second gate electrode G52 and the second gate spacer 512. The third gate insulating layer 523 may be disposed between the third gate electrode G53 and each of the first to fourth active patterns F51, F52, F53, F54. The third gate insulating layer 523 may be disposed between the third gate electrode G53 and the field insulating layer 505. The third gate insulating layer 523 may be disposed between the third gate electrode G53 and the third gate spacer 513.

The first source/drain region SD51 may be disposed between the first gate electrode G51 and the second gate electrode G52 on each of the first and second active patterns F51, F52. The second source/drain region SD52 may be disposed between the second gate electrode G52 and the third gate electrode G53 on each of the first and second active patterns F51, F52. The third source/drain region SD53 may be disposed between the first gate electrode G51 and the second gate electrode G52 on each of the third and fourth active patterns F53, F54. The fourth source/drain region SD54 may be disposed between the second gate electrode G52 and the third gate electrode G53 on each of the third and fourth active patterns F53, F54. The first interlayer insulating layer 540 may cover each of the first to fourth source/drain regions SD51, SD52, SD53, SD54 on the field insulating layer 505.

While embodiments according to the present disclosure have been described above with reference to the accompanying drawings, it will be understood that the present disclosure is not limited to the above embodiments and may be fabricated in a variety of different forms, and those skilled in the art to which the present disclosure belongs, with ordinary knowledge in the field, may recognize that it may be implemented in other specific forms without changing the technical idea or essential features of the present disclosure. Therefore, it should be understood that the above-described embodiments are non-limiting examples in all respects and not restrictive.

What is claimed is:

1. A semiconductor device comprising:
a substrate;
an active pattern extending in a first horizontal direction on the substrate;
a first gate electrode, a second gate electrode, and a third gate electrode each extending in a second horizontal direction on the active pattern, the second horizontal direction being different from the first horizontal direction, and the first gate electrode, the second gate electrode, and the third gate electrode being sequentially spaced apart from each other in the first horizontal direction;
a first source/drain region on the active pattern between the first gate electrode and the second gate electrode;
a second source/drain region on the active pattern between the second gate electrode and the third gate electrode;
a first source/drain contact extending in the second horizontal direction between the first gate electrode and the second gate electrode, the first source/drain contact electrically connected to the first source/drain region;
a second source/drain contact extending in the second horizontal direction between the second gate electrode and the third gate electrode, the second source/drain contact electrically connected to the second source/drain region;
a gate spacer extending in the second horizontal direction on both sidewalls of the second gate electrode in the first horizontal direction;
a first interlayer insulating layer covering each of the first source/drain region and the second source/drain region; and
a second interlayer insulating layer on the first interlayer insulating layer and in contact with at least a portion of sidewalls of the first source/drain contact in the second horizontal direction, the second interlayer insulating layer being a single layer, wherein
on the active pattern, a lower surface of the second interlayer insulating layer is in contact with each of an upper surface of the second gate electrode, an upper surface of the second source/drain contact, and an upper surface of the gate spacer between the second gate electrode and the second source/drain contact.

2. The semiconductor device of claim 1, wherein
an uppermost surface of the gate spacer between the first source/drain contact and the second gate electrode on the active pattern is higher than the upper surface of the gate spacer between the second gate electrode and the second source/drain contact on the active pattern.

3. The semiconductor device of claim 1, wherein
the upper surface of the gate spacer between the second gate electrode and the second source/drain contact on the active pattern is coplanar with the upper surface of the second gate electrode on the active pattern.

4. The semiconductor device of claim 1, wherein,
on the active pattern, the upper surface of the second source/drain contact is coplanar with the upper surface of the second gate electrode.

5. The semiconductor device of claim 1, wherein
on the active pattern, an upper surface of the third gate electrode is higher than the upper surface of the second gate electrode.

6. The semiconductor device of claim 1, wherein
a first portion of the first source/drain contact is on the first source/drain region,
a sidewall of the first portion of the first source/drain contact in the second horizontal direction is in contact with the first interlayer insulating layer,
a second portion of the first source/drain contact protrudes from the first portion of the first source/drain contact in a vertical direction,
a sidewall of the second portion of the first source/drain contact in the second horizontal direction is in contact with the second interlayer insulating layer, and
a width of the second portion of the first source/drain contact in the second horizontal direction is smaller than a width of the first portion of the first source/drain contact in the second horizontal direction.

7. The semiconductor device of claim 1, wherein
a first portion of the third gate electrode extends in the second horizontal direction on the active pattern, and
a second portion of the third gate electrode protrudes in a vertical direction from the first portion of the third gate electrode,
a sidewall of the second portion of the third gate electrode in the second horizontal direction is in contact with the second interlayer insulating layer,
a width of the second portion of the third gate electrode in the second horizontal direction is smaller than a width of the first portion of the third gate electrode in the second horizontal direction.

8. The semiconductor device of claim 7, wherein at least a portion of an upper surface of the first portion of the third gate electrode is in contact with the second interlayer insulating layer.

9. The semiconductor device of claim 1, wherein an uppermost surface of the third gate electrode is lower than an upper surface of the second interlayer insulating layer.

10. The semiconductor device of claim 1, further comprising:
a first wiring trench defined in the second interlayer insulating layer over an upper surface of the first source/drain contact;
a second wiring trench defined in the second interlayer insulating layer over an upper surface of the third gate electrode;
a first wiring pattern filling the first wiring trench, the first wiring pattern in contact with an upper surface of the second interlayer insulating layer adjacent to the first wiring trench, the first wiring pattern being in contact with the upper surface of the first source/drain contact; and
a second wiring pattern filling the second wiring trench, the second wiring pattern being in contact with the upper surface of the second interlayer insulating layer adjacent the second wiring trench, the second wiring pattern being in contact with the upper surface of the third gate electrode.

11. The semiconductor device of claim 10, wherein
a width of the first wiring trench in the first horizontal direction and a width of the first wiring trench in the second horizontal direction each increase as a level of first wiring trench becomes closer to the upper surface of the second interlayer insulating layer, and
of a width of the second wiring trench in the first horizontal direction and a width of the second wiring trench in the second horizontal direction each increase sequentially as a level of the second wiring trench gets closer to the upper surface of the second interlayer insulating layer.

12. The semiconductor device of claim 1, further comprising:
a first plurality of nanosheets stacked and spaced apart from each other in a vertical direction on the active pattern, the first plurality of nanosheets being surrounded by the first gate electrode;
a second plurality of nanosheets stacked and spaced apart from each other in the vertical direction on the active pattern, the second plurality of nanosheets spaced apart from the first plurality of nanosheets in the first horizontal direction, the second plurality of nanosheets surrounded by the second gate electrode; and
a third plurality of nanosheets stacked and spaced apart from each other in the vertical direction on the active pattern, the third plurality of nanosheets spaced apart from the second plurality of nanosheets in the first horizontal direction, the third plurality of nanosheets surrounded by the third gate electrode.

13. A semiconductor device comprising:
a substrate;
an active pattern extending in a first horizontal direction on the substrate;
a plurality of nanosheets stacked and spaced apart from each other in a vertical direction on the active pattern;
a gate electrode extending in a second horizontal direction on the active pattern, the second horizontal direction being different from the first horizontal direction, the gate electrode surrounding the plurality of nanosheets;
a first source/drain region on a first side of the gate electrode on the active pattern;
a second source/drain region on a second side of the gate electrode on the active pattern, the second side of the gate electrode being opposite the first side of the gate electrode in the first horizontal direction;
a first source/drain contact extending in the second horizontal direction from the first side of the gate electrode, the first source/drain contact being electrically connected to the first source/drain region, the first source/drain contact including a contact barrier layer and a contact filler layer, the contact barrier layer forming a portion of sidewalls and a lower surface of the first source/drain contact, and the contact filling layer filling a space between portions of the contact barrier layer;
a second source/drain contact extending in the second horizontal direction from the second side of the gate electrode, the second source/drain contact electrically connected to the second source/drain region;
a gate spacer extending in the second horizontal direction on both sidewalls of the gate electrode in the first horizontal direction;
a first interlayer insulating layer covering the first source/drain region and the second source/drain region; and
a second interlayer insulating layer in contact with at least a portion of the sidewalls of the first source/drain contact in the second horizontal direction on the first interlayer insulating layer, the second interlayer insulating layer being in contact with at least a portion of sidewalls of the contact filling layer in the second horizontal direction, the second interlayer insulating layer being a single layer, wherein
an uppermost surface of the gate spacer between the first source/drain contact and the gate electrode on the active pattern is higher than an upper surface of the gate spacer between the gate electrode and the second source/drain contact on the active pattern.

14. The semiconductor device of claim 13, wherein, on the active pattern, an upper surface of the second source/drain contact is lower than an uppermost surface of the first source/drain contact.

15. The semiconductor device of claim 13, wherein an uppermost surface of the first source/drain contact is lower than an upper surface of the second interlayer insulating layer.

16. The semiconductor device of claim 13, wherein a material of the second interlayer insulating layer is different from a material of first interlayer insulating layer.

17. The semiconductor device of claim 13, wherein, on the active pattern, an uppermost surface of the contact filling layer is higher than an uppermost surface of the contact barrier layer.

18. The semiconductor device of claim 13, wherein, on the active pattern, an uppermost surface of the contact filling layer is coplanar with an uppermost surface of the contact barrier layer.

19. The semiconductor device of claim 13, further comprising:
an air gap between the sidewalls of the contact filling layer in the first horizontal direction and sidewalls of the second interlayer insulating layer on the active pattern,
the air gap exposing an uppermost surface of the contact barrier layer on the active pattern.

20. A semiconductor device comprising:
a substrate;
a first active pattern extending in a first horizontal direction on the substrate;
a second active pattern extending in the first horizontal direction on the substrate, the second active pattern spaced being apart from the first active pattern in a second horizontal direction, the second horizontal direction being different from the first horizontal direction;
a first gate electrode, a second gate electrode and a third gate electrode each extending in the second horizontal direction on the first active pattern and the second active pattern, the first gate electrode, the second gate electrode, and the third gate electrode being sequentially spaced apart from each other in the first horizontal direction;
a first source/drain region between the first gate electrode and the second gate electrode on the first active pattern;
a second source/drain region between the second gate electrode and the third gate electrode on the first active pattern;
a third source/drain region between the first gate electrode and the second gate electrode on the second active pattern;
a fourth source/drain region between the second gate electrode and the third gate electrode on the second active pattern;
a first source/drain contact extending in the second horizontal direction between the first gate electrode and the second gate electrode, the first source/drain contact electrically connected to each of the first source/drain region and the third source/drain region;
a second source/drain contact extending in the second horizontal direction between the second gate electrode and the third gate electrode, the second source/drain contact electrically connected to each of the second source/drain region and the fourth source/drain region;
a gate spacer extending in the second horizontal direction on both sidewalls of the second gate electrode in the first horizontal direction;
a first interlayer insulating layer covering each of the first source/drain region, the second source/drain region, the third source/drain region, and the fourth source/drain region; and
a second interlayer insulating layer in contact with at least a portion of sidewalls of the first source/drain contact in the second horizontal direction on the first interlayer insulating layer, the second interlayer insulating layer being a single layer,
wherein, on the first active pattern, a lower surface of the second interlayer insulating layer is in contact with each of an upper surface of the second gate electrode, an upper surface of the second source/drain contact, and an upper surface of the gate spacer between the second gate electrode and the second source/drain contact,
wherein, on the second active pattern, the lower surface of the second interlayer insulating layer is in contact with each of the upper surface of the second gate electrode, an upper surface of the first source/drain contact, and the upper surface of the gate spacer between the first source/drain contact and the second gate electrode,
wherein an uppermost surface of the gate spacer between the first source/drain contact and the second gate electrode on the first active pattern is higher than the upper surface of the gate spacer between the second gate electrode and the second source/drain contact on the first active pattern, and
wherein the upper surface of the gate spacer between the first source/drain contact and the second gate electrode on the second active pattern is lower than the uppermost surface of the gate spacer between the second gate electrode and the second source/drain contact on the second active pattern.
